(19) United States
(12) Patent Application Publication
(10) Pub. No.: US 2019/0148574 A1
(43) Pub. Date: May 16, 2019

(54) Superstrates Incorporating Effectively Transparent Contacts and Related Methods of Manufacturing

(71) Applicant: California Institute of Technology, Pasadena, CA (US)

(72) Inventors: Rebecca Saive, Enschede (NL); Harry A. Atwater, South Pasadena, CA (US); Sophia Coplin, Pasadena, CA (US); Michael Kelzenberg, Pasadena, CA (US); Sisir Yalamanchili, Pasadena, CA (US); Colton Bukowsky, Pasadena, CA (US); Thomas Russell, Pasadena, CA (US)

(73) Assignee: California Institute of Technology, Pasadena, CA (US)

(21) Appl. No.: 16/192,704

(22) Filed: Nov. 15, 2018

Related U.S. Application Data
(60) Provisional application No. 62/586,591, filed on Nov. 15, 2017.
(60) Provisional application No. 62/742,069, filed on Oct. 5, 2018.

(51) Int. Cl. H01L 31/0224; H01L 31/0216; H01L 31/18; H01L 31/0236

(52) U.S. Cl. CPC H01L 31/022475; H01L 31/02167; H01L 31/0465; H01L 31/1884; H01L 31/02366; H01L 31/022433

(57) ABSTRACT

Superstrates containing ETCs in accordance with various embodiments of the invention can be implemented to reduce optical losses by decreasing the thickness of the TCO and by reducing or eliminating shading losses of metal grid fingers. ETC superstrates can include a transparent material with grooves, which can be infilled with reflective, conductive material(s) such as but not limited to silver and aluminum. In further embodiments, the grooves are triangular-shaped. ETC superstrates can enable a significant reduction in the TCO thickness required for current extraction with a high fill factor. By reducing the thickness of the TCO layer in solar cells, the short circuit current density can be enhanced by more than 1 mA/cm² due to decreased parasitic absorption and optimized antireflection properties.

### CROSS-REFERENCE TO RELATED APPLICATIONS

The current application claims the benefit of and priority under 35 U.S.C. § 119(e) to U.S. Provisional Patent Application No. 62/586,591 entitled “Transparent, Conductive and Lightweight Superstrates for Perovskite, Thin Film and Tandem Solar Cells,” filed Nov. 15, 2017 and U.S. Provisional Patent Application No. 62/742,069 entitled “Transparent, Conductive and Lightweight Superstrates for Perovskite, Thin Film and Tandem Solar Cells,” filed Oct. 5, 2018. The disclosures of U.S. Provisional Patent Application Nos. 62/586,591 and 62/742,069 are hereby incorporated by reference in their entireties for all purposes.

### STATEMENT REGARDING FEDERALLY SPONSORED RESEARCH OR DEVELOPMENT

This invention was made with government support under Grant No. DE-EE0004946/T-114930 awarded by the Department of Energy. The government has certain rights in the invention.

### FIELD OF THE INVENTION

The present invention generally relates to superstrates and, more specifically, to superstrates for solar cell applications.

### BACKGROUND

Photovoltaics refer to a class of methods for converting light into electricity using the photovoltaic effect. Due to technological advances in recent years, photovoltaics are becoming a more viable, carbon-free source of electricity generation. A photovoltaic system typically employs an array of solar cells to generate electrical power. Solar cells can be made of a variety of semiconductors, typically a silicon based structure, acting as a substrate and can include front and rear contacts that are used to conduct current out of the solar cell. The conversion process involves the absorption of light rays by what can be referred to as the active region of the solar cell, which can excite electrons in the substrate into a higher state of energy. The excitation allows the electrons to move as an electric current that can then be extracted to an external circuit and stored.

### SUMMARY OF THE INVENTION

Superstrates incorporating effectively transparent contacts in accordance with various embodiments of the invention can be implemented in many different ways. One embodiment includes an optoelectronic device including a photoabsorbing surface and a polymer layer including a first surface and a second surface, wherein the first surface defines a plurality of triangular grooves filled with a conductive material, wherein the filled triangular grooves form three-dimensional contacts that includes at least one surface such that at least a portion of radiation incident on the surface is redirected onto the photoabsorbing surface.

In another embodiment, the photoabsorbing surface includes a material that is one of: a III-V material, GaAs, CdTe, GICS, perovskite, and silicon. III-V material, GaAs, CdTe, GICS, perovskite, and silicon.

In a further embodiment, the optoelectronic device further includes a plurality of existing metallic contacts on the photoabsorbing surface.

In still another embodiment, the optoelectronic device further includes solder material in contact with at least one of the existing contacts and the conductive material of at least one of the plurality of triangular grooves.

In a still further embodiment, the optoelectronic device further includes a layer of transparent conductive oxide in contact with the photoabsorbing surface and the polymer layer.

In yet another embodiment, the layer of transparent conductive oxide includes a transparent conductive oxide material that is one of: indium tin oxide and fluorine doped tin oxide.

In a yet further embodiment, the layer of transparent conductive oxide has a thickness of less than 200 nm.

In another additional embodiment, the polymer layer includes a material that is one of: ethylene-vinyl acetate, polydimethylsiloxane, polyurethane, and polymethylmethacrylate.

In a further additional embodiment, the conductive material includes silver nanoparticle ink.

In another embodiment again, the conductive material is a composite including a triangular core in contact with at least two reflective surfaces.

In a further embodiment again, at least one of the plurality of triangular grooves have a height-to-width aspect ratio of at least 2:1.

In still yet another embodiment, at least one of the plurality of triangular grooves have a height of approximately 15 μm and a width of approximately 5 μm.

In a still yet further embodiment, the plurality of triangular grooves is in a grid pattern.

In still another additional embodiment, the polymer layer has a thickness of less than 500 μm.

In a still further additional embodiment, the optoelectronic device further includes a sub silicon solar cell.

In still another embodiment again, the optoelectronic device further includes a lamination layer in contact with the second surface of the polymer layer.

A still further embodiment again includes a method of manufacturing a superstrate integrated with an optoelectronic device, the method including providing a layer of transparent polymer, forming a plurality of grooves within the layer of transparent polymer, infilling the plurality of grooves with a conductive material, and integrating the layer of transparent polymer with an optoelectronic device.

In yet another additional embodiment, the plurality of grooves is infilled using an electroplating process.

In a yet further additional embodiment, the optoelectronic device includes a layer of transparent conductive oxide and the layer of transparent polymer is in contact with the layer of transparent conductive oxide after integration with the optoelectronic device.

A yet another embodiment again includes an optoelectronic device including a photoabsorbing surface including perovskite, a layer of polydimethylsiloxane in contact with the photoabsorbing surface, and a layer of indium tin oxide in contact with the photoabsorbing surface and the layer of polydimethylsiloxane, wherein the layer of polydimethylsiloxane includes a first surface and a second surface, the first surface defines a plurality of triangular grooves filled with silver nanoparticle ink, and at least one of the plurality of triangular grooves have a cross-section with a height-to-width ratio of at least 2:1.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description will be more fully understood with reference to the following figures and data graphs, which are presented as exemplary embodiments of the invention and should not be construed as a complete recitation of the scope of the invention.

FIG. 1 conceptually illustrates a profile view of a superstrate incorporating effectively transparent contacts in accordance with an embodiment of the invention.

FIG. 2 conceptually illustrates a process for the fabrication of a superstrate incorporating effectively transparent contacts in accordance with an embodiment of the invention.

FIG. 3 shows SEM micrographs of micro-machined Si master molds in accordance with various embodiments of the invention.

FIG. 4 conceptually illustrates an infilling process of a superstrate in accordance with an embodiment of the invention.

FIG. 5 conceptually illustrates a profile view of a filled superstrate having concave ink surfaces in accordance with an embodiment of the invention.

FIG. 6 conceptually illustrates an infilling process of a superstrate utilizing a stretching method in accordance with an embodiment of the invention.

FIG. 7 conceptually illustrates a filling process of a superstrate utilizing a removable surface in accordance with an embodiment of the invention.

FIG. 8 conceptually illustrates a filling process of a superstrate utilizing an electroplating process in accordance with an embodiment of the invention.

FIGS. 9 and 10 conceptually illustrate filling processes of superstrates utilizing a polymer resin coating in conjunction with an electroplating process in accordance with an embodiment of the invention.

FIG. 11 conceptually illustrates a filling process of a superstrate utilizing the application of pressure on an ink-filled reservoir in accordance with an embodiment of the invention.

FIG. 12 conceptually illustrates an infilling process utilizing doctor blading techniques in accordance with an embodiment of the invention.

FIGS. 13 and 14 conceptually illustrate effectively transparent contact gridlines with single-conductor and multi-conductor busbars in accordance with an embodiment of the invention.

FIG. 15 conceptually illustrates an ETC superstrate with a soldering layer in accordance with an embodiment of the invention.

FIG. 16 conceptually illustrates a cutting process for large-scale fabrication superstrates incorporating effectively transparent contacts in accordance with an embodiment of the invention.

FIG. 17 conceptually illustrates a filling process for large-scale fabrication of superstrates incorporating effectively transparent contacts in accordance with an embodiment of the invention.

FIG. 18 conceptually illustrates an overview of an effectively transparent contact superstrate manufacturing line in accordance with an embodiment of the invention.

FIG. 19 conceptually illustrates a schematic of a perovskite solar cell with an effectively transparent contact superstrate in accordance with an embodiment of the invention.

FIG. 20 conceptually illustrates the integration of individual solar cells along with the addition of a lamination layer in accordance with an embodiment of the invention.

FIG. 21 conceptually illustrates a single effectively transparent contact superstrate layer placed on top of multiple solar cells in accordance with an embodiment of the invention.

FIG. 22 conceptually illustrates an effectively transparent contact superstrate incorporating a layer of transparent conductive oxide in accordance with an embodiment of the invention.

FIG. 23 conceptually illustrates an effectively transparent contact superstrate with a top transparent conductive oxide layer placed on top of the front glass of a thin-film solar module in accordance with an embodiment of the invention.

FIG. 24 conceptually illustrates an effectively transparent contact superstrate integrated with a thin-film solar cell in accordance with an embodiment of the invention.

FIG. 25 conceptually illustrates the use of a parabolic filling profile for the integration of a superstrate incorporating effectively transparent contacts on top of existing contacts on a silicon PERC cell in accordance with an embodiment of the invention.

FIG. 26 conceptually illustrates the use of a parabolic filling profile for the integration of a superstrate incorporating effectively transparent contacts on top of existing contacts on a III-V solar cell in accordance with an embodiment of the invention.

FIG. 27 conceptually illustrates the use of a parabolic filling profile and a soldering layer for the integration of a superstrate incorporating effectively transparent contacts on top of existing contacts on solar cell in accordance with an embodiment of the invention.

FIG. 28 conceptually illustrates a tandem solar cell utilizing effectively transparent contact superstrates in accordance with an embodiment of the invention.

FIG. 29 conceptually illustrates the use of a superstrate incorporating effectively transparent contacts as a sacrificial mold in accordance with an embodiment of the invention.

FIG. 30 shows measured transmission of a bare soda-lime glass superstrate, ETC superstrate, and 1-reflection of bare soda-lime glass without indium tin oxide in accordance with an embodiment of the invention.

FIG. 31 shows simulated short circuit density as a function of indium tin oxide thickness for two different types of indium tin oxide in accordance with an embodiment of the invention.

FIG. 32A shows measured and simulated external quantum efficiency and 1-reflection in accordance with an embodiment of the invention.

FIG. 32B shows measured integrated external quantum efficiency in accordance with an embodiment of the invention.

FIG. 33A shows optically simulated effective transparency and calculated sheet resistance of the superstrates as a function of the incident angle and the periodicity of the effectively transparent contacts in accordance with an embodiment of the invention.

FIG. 33B shows optically simulated effective transparency and calculated sheet resistance of the superstrates as a function of the incident angle and the height-to-width-ratio of the effectively transparent contacts in accordance with an embodiment of the invention.

FIG. 33C shows optically simulated effective transparency and calculated sheet resistance of the superstrates as a function of the incident angle and the contact size factor in accordance with an embodiment of the invention.

### DETAILED DESCRIPTION

Turning now to the drawings, effectively transparent and highly conductive superstrates for optoelectronic applications are illustrated. Superstrates in accordance with various embodiments of the invention can be utilized for a variety of applications. For example, in solar cell applications, a superstrate incorporating effectively transparent contacts (“ETCs”) can be implemented to boost solar cell power output. In conventional solar cells, metal contacts are typically required for charge extraction from solar cells. Traditional screen-printed metal contact grids typically cover up to ˜5% of the cell front surface, blocking sunlight from reaching the photovoltaic absorber below. These shading losses are among the largest causes of performance loss in most solar cells. For certain solar cells, another major optical loss mechanism emerges from the transparent conductive oxide (“TCO”) needed to provide low loss lateral charge transport. These TCOs can exhibit parasitic absorption that leads to significant loss in current density. Furthermore, in large-scale devices, the high photocurrents can require metal grid fingers in order to achieve low resistance. These metal fingers can lead to further optical losses due to geometric shading.

Superstrates containing ETCs (“ETC superstrates”) in accordance with various embodiments of the invention can be implemented to reduce optical losses by decreasing the thickness of the TCO and by reducing or eliminating shading losses of metal grid fingers. The superstrates can incorporate effectively transparent contacts (“ETCs”) that enable a significant reduction in the TCO thickness required for current extraction with a high fill factor. By reducing the thickness of the TCO layer in solar cells, the short circuit current density can be enhanced by more than 1 mA/cm² due to decreased parasitic absorption and optimized antireflection properties. However, in order to provide low-loss lateral charge transport, decreased TCO thickness requires the introduction of metal grid fingers. Effectively transparent contacts in accordance with various embodiments of the invention are microscale fingers capable of redirecting incoming light towards the active area of the solar cells. As such, the contacts can be placed closely together without introducing shading losses. In some embodiments, integrating ETCs in solar cell superstrates can lead to high conductivity (<5 Ω/sq sheet resistance). For some applications, such as in the case of perovskite solar cells, the absorption within the active layer can even exceed the absorption of cells without metal grids due to light trapping. As discussed above, ETCs in accordance with various embodiments of the invention can also be utilized to reduce shading losses. In many embodiments, the ETCs are triangular shaped, high-aspect-ratio silver gridlines. When sunlight impinges the ETC gridlines, the incident rays can be efficiently reflected towards the active area of the solar cell, rather than being reflected away and lost. Such techniques can substantially reduce and/or eliminate the shading loss problem and boosts the solar cell power output. In some embodiments, solar cell power output can be increased by ˜5%. In a number of embodiments, ETCs can achieve effective optical transparency of greater than 99% even at relatively dense grid spacing and over a wide range of angles of incidence. In many cases, the integration of ETCs can allow for a transparency of ˜99.9%.

Superstrates containing ETCs can be constructed in many different ways. In many embodiments, ETC superstrates include a transparent material with grooves, which can be infilled with reflective, conductive material(s) such as but not limited to silver and aluminum. In further embodiments, the grooves are triangular-shaped. In some embodiments, the ETC superstrate incorporates one or more transparent conductors on the side of the ETCs, such as but not limited to TCOs such as indium tin oxide (“ITO”), conductive polymers such as PEDOT:PSS, nanowire meshes such as silver nanowires. ETC superstrates can also incorporate transparent layers on the side opposite the ETCs, such as but not limited to glass layers and antireflective coatings The ETC superstrate can further incorporate other elements of benefit depending on the given application. For example, in solar cell applications, bus bars or tabbing pads can also be incorporated. Additionally, features to aid in attaching the ETC superstrate to the solar cell, such as but not limited to voids and indentations can be incorporated to provide clearance around bus bars or tabbing areas. ETC superstrates in accordance with various embodiments of the invention can be incorporated in many different applications. In many embodiments, the ETC superstrate can be applied to the front surface of a solar cell, such as but not limited to a crystalline Si and a III-V solar cell, by aligning the ETC gridlines with existing conventional gridline contacts on the solar cell. The composite can then be laminated or mechanically pressed. Some types of solar cells, such as amorphous heterojunction Si cells, may have a transparent conductive layer, such as an ITO layer, as the existing contact surface instead of conventional gridlines. In such cases, the ETC superstrate can be aligned using another point of reference. For example, the alignment can be performed by centering the ETC superstrate on the solar cell. In either case, the ETC superstrate can incorporate pre-treated surfaces, adhesives, and/or solder pastes to enable reliable mechanical attachment between the superstrate and the solar cell and/or to enable reliable electrical contact between the ETC gridlines and the solar cell's existing contacts during the lamination process. In the case of bifacial solar cells, which receive sunlight from either or both sides, ETC superstrates can, in the manner described above or any other method, be applied to either or both sides of the solar cell. As can readily be appreciated, the specific manner in incorporating ETC superstrates can depend on the specific application. For example, some embodiments include a solar cell with a CdTe layer that is deposited via vapor transport deposition (“VTD”), a process that occurs at temperatures around 400 C. In such embodiments, the ETC superstrate can be applied to the front surface of the solar cell, rather than as a platform onto which the CdTe is deposited via VTD since the ETC Superstrate cannot withstand the high temperatures at which the VTD process takes place.

In many embodiment, the ETC superstrate can be used as a platform onto which additional layers are deposited in order to fabricate the solar cell. For example, a perovskite solar cell can be fabricated on an ETC superstrate having an ITO-coated surface by sequentially depositing: a hole transport layer (“HTL”) such as but not limited to nickel oxide, a perovskite layer such as but not limited to methylammonium lead iodide, an electron transport layer (“ETL”) such as but not limited to PCBM, and a back contact electrode such as but not limited to silver. Such layers can be deposited by a variety of methods including but not limited to solution processing, spin coating, doctor blading, slot die casting, spraying, spray pyrolysis, vacuum deposition, evaporation, sputtering, and/or atomic layer deposition. Additionally, other types of thin-film solar cells can be deposited onto ETC superstrates, including but not limited to CdTe, CIGS, organic, dye-sensitized, and tandem combinations of thin-film solar cells. Further discussions of superstrates, computational simulations, and related methods of integration and fabrication in accordance with various embodiments of the invention can be found in the sections below.

The above described approach constitutes an effective and scalable way of enhancing the short-circuit current density in perovskite solar cells and incorporates materials that are widely used in the photovoltaic industry. Using such techniques, the area fraction devoted to macroscopic grid fingers and busbars can be further reduced on large-scale solar cells and modules as compared with conventional designs. Furthermore, ETC superstrates may find application in thin film tandem solar cell architectures as well as in other optoelectronic devices. In addition, ETC superstrates can be fabricated as thin and lightweight membranes that are particularly interesting for space, aviation, and mobile applications. In many embodiments, sol-gel ETC membranes with a thickness of 40-80 μm and a specific weight of 2.5±0.1 mg/cm² can be implemented. Compared to a standard glass substrate, such ETC membranes can be 1000 times lighter. As can readily be appreciated, any of a variety of different membrane materials, such as but not limited to PDMS and space resistant polymers, can be utilized.

### ETC Superstrates

Certain types of solar cells contain existing metal contacts on their front surfaces. Such conventional, flat metal contacts can cause shading optical losses. ETC superstrates in accordance with various embodiments of the invention can be implemented to address these shading losses and to improve the electrical conductivity of the front grid. ETC superstrates can be formed in many different configurations. In many embodiments, the ETC superstrate includes a polymer layer with embedded effectively transparent contacts. The polymer layer can be made of various materials, including but not limited to PDMS, ethylene-vinyl acetate (“EVA”), polyurethane, polymethylmethacrylate (“PMMA”), or any other suitable polymer and materials. Effectively transparent contacts can also be fabricated and implemented in many different ways. In some embodiments, the ETCs are micro-scale metal contacts. In further embodiments, the ETCs are silver contacts. ETCs can also be implemented in a variety of different shapes. In a number of embodiments, the ETCs have triangular cross-sections. By incorporating ETCs in the polymer, charge conduction can be enabled while maintaining the optical transparency of the polymer layer.

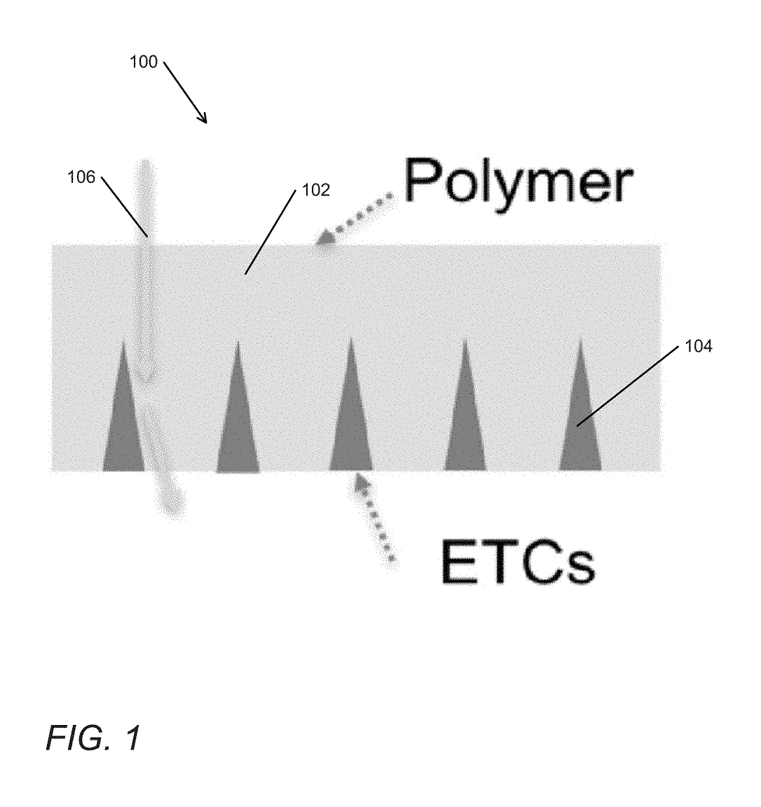

FIG. 1 conceptually illustrates a profile view of an ETC superstrate in accordance with an embodiment of the invention. As shown, the superstrate 100 includes a polymer layer 102 with embedded triangular-shaped contacts 104. During operation, incoming light 106 incident on the triangular contacts 104 can be redirected to pass through the superstrate, resulting in an effectively transparent superstrate. Although FIG. 1 illustrates a specific ETC superstrate structure, any of a number of different configurations can be implemented. Various shapes and aspect ratios of triangular contacts can be utilized. In many embodiments, the triangular contacts have a height-to-width aspect ratio of at least 2:1. In further embodiments, the triangular contacts have a height-to-width aspect ratio of at least 3:1. As described above, the layer in which the contacts are embedded can also vary in material and construction. Additionally, the pitch or ETC-to-ETC distance can be an irregular pattern, which can be used to suppress higher order diffraction patterns when light passes through the ETC superstrate.

ETC superstrates can be implemented as a drop-in replacement for III-V, thin-film, and silicon solar cell manufacturers by either replacing the conventional EVA/PDMS encapsulant material or replacing the transparent conductive oxide layer used for thin-film solar cell technologies that leads to unwanted parasitic absorption. Such ETC superstrates can be constructed to be compatible with current solar cell manufacturing methods, allowing for the integration of the ETC superstrates in the existing production line of solar cell manufacturers. The strength of the ETC superstrate is that it can provide 99.9% optical transparency by incorporating ETCs that redirect the incoming sunlight. In addition, the ETCs can be electrically connected to the existing contacts on the solar cell, which improves the finger resistance and sheet resistance. This allows for optimized grid-layouts, optimized doping levels, and new cell designs that can maximize the use of ETC superstrates. For example, by placing the ETCs close together, the doping levels in the emitter layer can change, reducing the parasitic absorption.

As the industry moves toward finer metal grid lines, higher aspect ratio metal contacts can be needed to provide sufficient charge extraction, which scales with the cross-section of the metal contact. However, just reducing the finger line width will not be sufficient to boost the efficiency of solar cells since the sheet resistance will also increase. By incorporating ETCs, finer line widths can be enabled, reducing or eliminating shading losses while maintaining a sufficient electrical charge extraction since the ETC can be designed to have aspect ratio that is a factor of 3-6× larger than the conventional screen-printed or flat metal contacts.

### Fabrication of ETC Superstrates

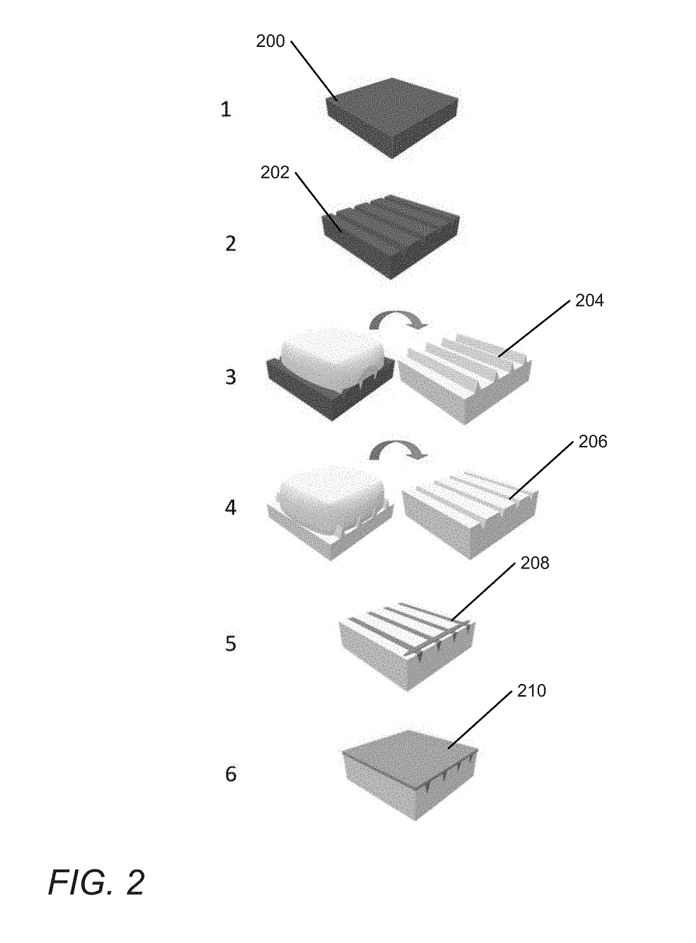

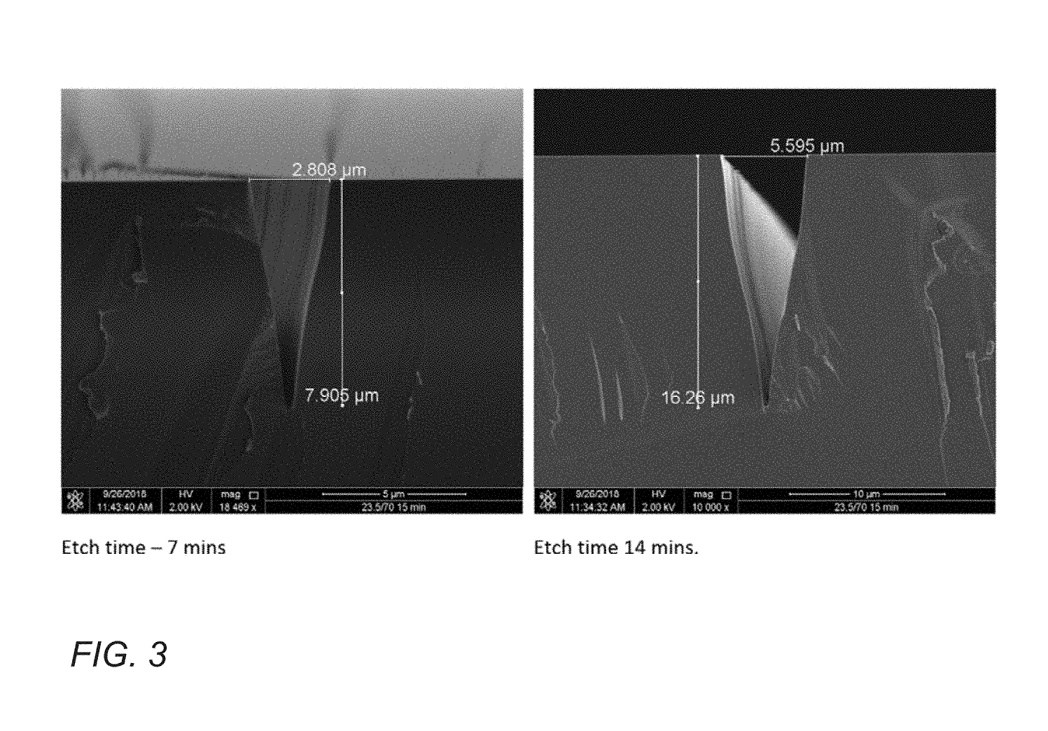

ETC superstrates in accordance with various embodiments of the invention can be fabricated in many different ways. In some embodiments, machining of a master mold and then soft-imprinting polymer replication processes are utilized to form the polymer layer of the ETC superstrate. FIG. 2 conceptually illustrates such a process. As shown, the process starts with providing a master mold substrate 200. Different types of substrates, such as but not limited to a silicon wafer, can be utilized. An etch mask material, such as 200 nm of Al₂O₃, is applied to the surface of the substrate and then patterned using photolithography. Dry-etch micromachining can be performed using an Oxford Dielectric System 100 ICP/RIE tool. The etching is performed at −80° C. table temperature with a SF6/O2 plasma at a gas ratio of 35:6 and a pressure of 10 mTorr. The forward power is 8 W and the inductively coupled power is 900 W. Increasing O₂ content typically increases the slope of the etch sidewalls. A gas ratio of 14:3 can produce triangular grooves of ˜1:2 aspect ratio, whereas 35:6 ratio can produce aspect ratios of ˜1:3. The resulting silicon master mold 202 is created with the desired pattern of triangular grooves. Cross-sectional SEM micrographs of such micro-machined Si master molds are shown in FIG. 3. Various sizes and shapes of grooves can be utilized depending on the specific requirements of a given application. In many embodiments, the lines are approximately 5 μm wide and approximately 15 μm high with a periodicity of approximately 80 μm.

The silicon master mold 202 can be used to make a copy via a two-step copying process. First, a negative mold 204 can be formed from the master mold by casting a forming a suitable material, such as PDMS, against the master mold. From the negative copy, a positive imprint 206 can then be formed by casting or forming the ETC superstrate polymer material against the negative mold 204. Such copies can be formed in a number of different ways using different materials. In many embodiments, uncured PDMS resin can be applied on the surface of soda-lime glass, and then the desired mold can be pressed into the PDMS layer such that, after curing, the thin PDMS layer features triangular cross-section grooves. The thickness of the PDMS layer can vary depending on the specific requirements of a given application. In some embodiments, the PDMS layer has a thickness of approximately 40 μm outside of the grooves. The positive imprint 206 can then be infilled 208 and encapsulated or integrated 210 for various purposes. Although FIG. 2 illustrates a specific process for fabricating an ETC superstrate, any of a number of different processes can be utilized as appropriate depending on the given application.

Instead of working with a negative master, a positive master can be fabricated with upstanding triangular features on the silicon substrate. Master molds with triangular cross-section lines can be prepared with a variety of different methods. In many embodiments, the positive master is fabricated using a two-photon lithography process. In such embodiments, the copying process no longer includes the negative copy step. In the illustrative embodiment, the copy is made of EVA. However, any of a number of different materials can also be utilized. Such materials can include but not limited to PDMS, polyurethane, PMMA, PET, and various suitable polymers.

In many embodiments, the fabrication process can include a step where one polymer layer is used as a mold or tool to cast or emboss another polymer layer of the same material. However, it can be critical that the polymer layers do not adhere to one another. In such embodiments, a surface treatment step can be performed to prevent unwanted adhesion. Different surface treatments can be used depending on the type of polymers used. For example, in embodiments including a PDMS copy, the PDMS stamp can be surface functionalized the with an oxygen plasma treatment and subsequent coating with a (3-(N-Ethylamino)isobutyl)trimethoxysilane (4 wt % in methanol, Gelest SIE4886.0) self-assembled monolayer. In EVA-PDMS steps, the surface can be treated with oxygen plasma followed by a TEFLON™ or silane treatment.

After the polymer layer of the superstrate is fabricated, the grooves can be filled with a conductive ink, such as but not limited to silver nanoparticle ink, to form the contacts. In many embodiments, the contacts are formed with aluminum. In some embodiments, the contacts are formed with a core and outer layer. In further embodiments, the core is formed with copper. As can readily be appreciated, various materials can be utilized to form ETCs, and the choice of which can depend on the specific requirements of a given application. After the infilling step, a curing step can be performed. In some embodiments, a two-step curing process is performed. First, the solvent from the ink can be removed using a variety of different methods, including but not limited to vacuum treatment, annealing, applying a voltage, HCl, and photocuring. Afterwards, a secondary curing step can be performed in order to reduce the resistance of the conductive ink and provide a sufficient sheet resistance of the ETC superstrate. The secondary curing step can be performed with any of the methods mentioned above.

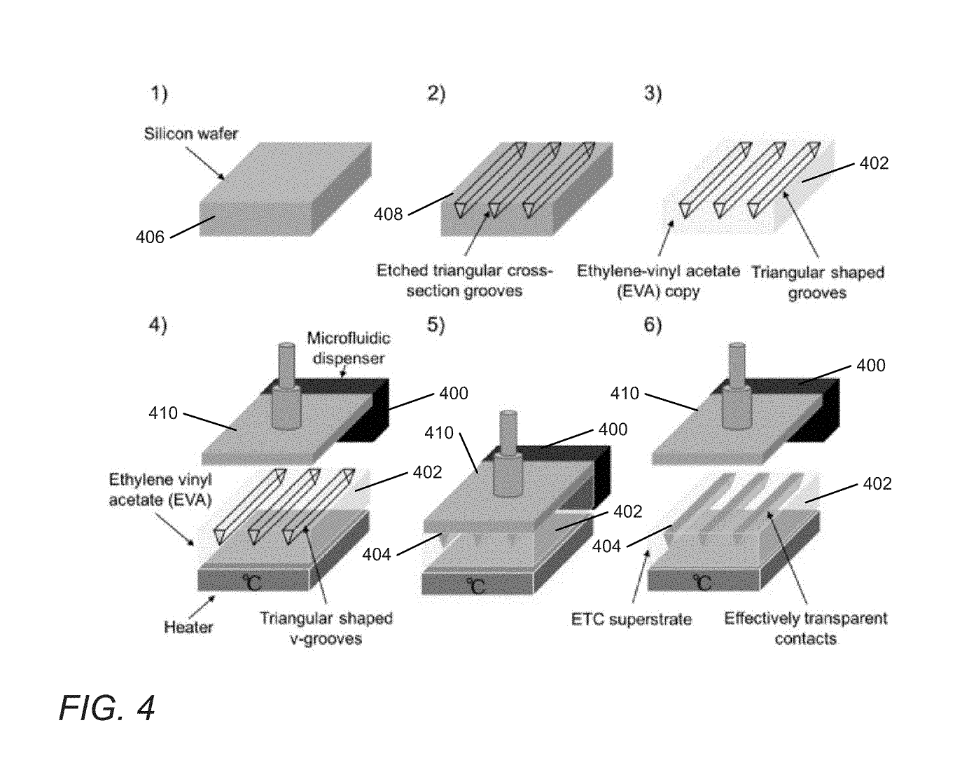

The filling process can be achieved using any of a number of different methods. For example, the process shown in FIG. 4 utilizes a microfluidic dispenser 400 to fill the polymer layer 402 with conductive ink to form ETCs 404. In the illustrative embodiment, the polymer layer 402 is an EVA copy formed using a silicon wafer substrate 406 formed into a master mold 408 along with the two-step copying process described above. A top plate 410 is used to form channels to facilitate the filling process. In some embodiments, capillary flow can be utilized to fill the triangular grooves/channels. In such embodiments, the conductive ink can be placed next to or inside the grooves/channels via micro-nozzles and/or capillary flow. In a number of embodiments, an array of micro-dispenser nozzles can be used to deliver the ink to each individual groove/channel. In further embodiments, positive and/or negative pressure can be used to facilitate the capillary filling process.

Depending on the surface energy of the polymer material utilized, the filling profile of the ink can differ. In many embodiments, an oxygen plasma surface treatment step can be performed to improve surface wetting. In a number of embodiments, the oxygen plasma treatment was conducted for approximately 36 seconds. In some embodiments, capillary action was utilized in order to prevent ink spilling outside of the groves. The oxygen plasma treatment can render the polymer surface hydrophilic to facilitate the filling process. Such properties can allow for a capillary flow of more than 1 cm from one side and therefore a distance of more than 2 cm in between the ink infilling area. This length scale can be comparable with the distance of busbars in macroscopic devices. Changes to the channel geometry and surface treatment can result in capillary flow over longer or shorter distances.

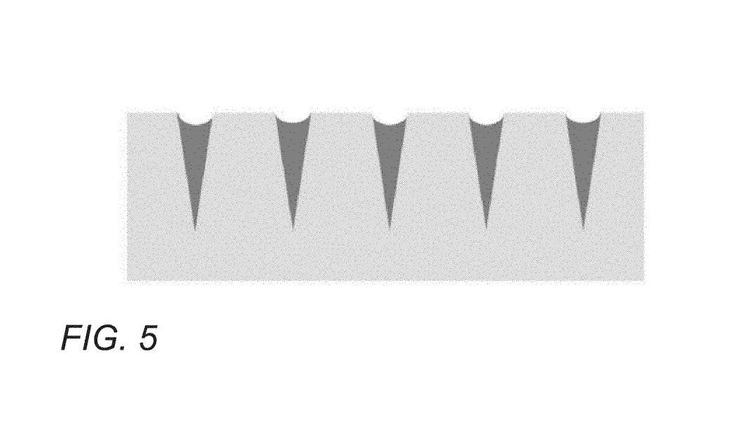

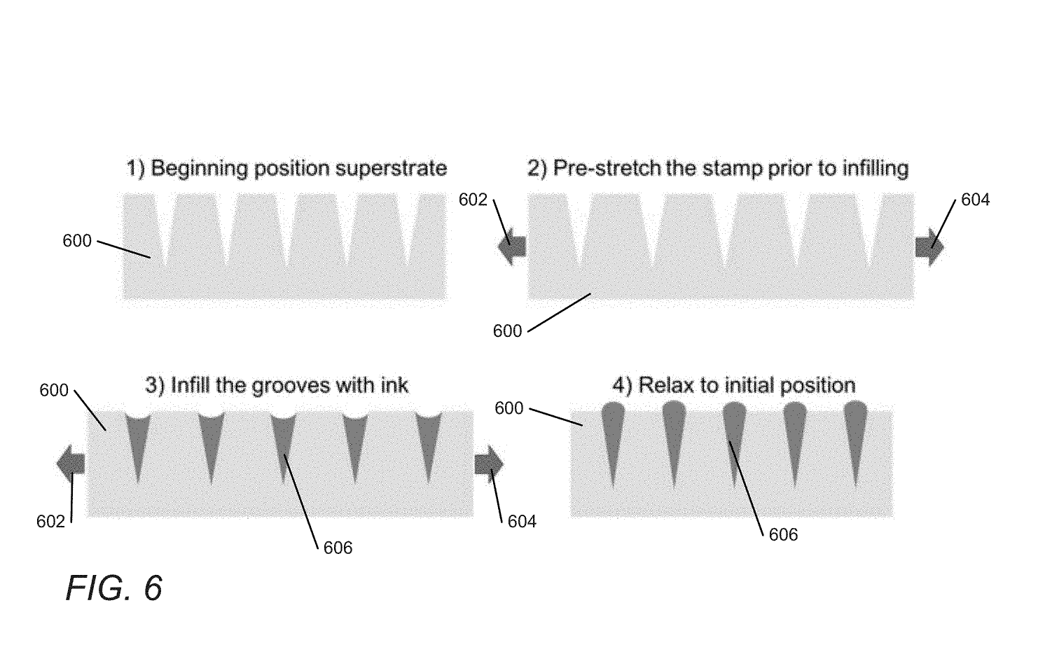

Due to the strong wetting of ink inside the grooves, a concave ink surface typically forms. This parabolic profile can depend on the different surface energies of the materials used and on the type of filling techniques used. FIG. 5 conceptually illustrates a profile view of a filled superstrate having concave ink surfaces in accordance with an embodiment of the invention. In many cases, the parabolic filling profile can be undesirable as the contact will not form a good electrical contact with the layer on which it is integrated. One method of solving this issue includes the use of a stretching step. FIG. 6 conceptually illustrates a stretching method for the filling process of a superstrate in accordance with an embodiment of the invention. As shown, prior to infilling the grooves of the polymer layer 600 with a conductive ink, the polymer can be pre-stretched in a direction perpendicular to the direction of the grooves. Arrows 602, 604 indicates the direction of force applied. Once the polymer layer 600 is stretched, the grooves can be filled with ink 606 through any of the processes described above. The polymer layer is then relaxed, reducing the volume of the grooves (compared to the stretched grooves), infilling the entirety of the grooves or even above the polymer surface, creating a hyperbolic profile. By precisely controlling the forces by which the polymer is stretched, the filling profile can be changed and adapted in order to form a good electrical contact between the ETCs and the layer on which the superstrate will be attached, such as but not limited to solar cells, windows, and displays.

Another method for changing the filling profile includes a secondary filling step. In such embodiments, the capillary flow process to infill the grooves is repeated twice. First, the grooves are infilled with a conductive ink via capillary flow. The conductive ink can then be cured to remove solvent from the ink to prevent the ink from changing shape. Afterwards, the filling step is repeated, allowing for filling profile to change. In many embodiments, the second filling step is utilized to completely fill the grooves, allowing the formed ETCs to form a good electrical contact with the layer that on which the superstrate will be attached, or providing a suitably smooth surface onto which deposit layers of a solar cell.

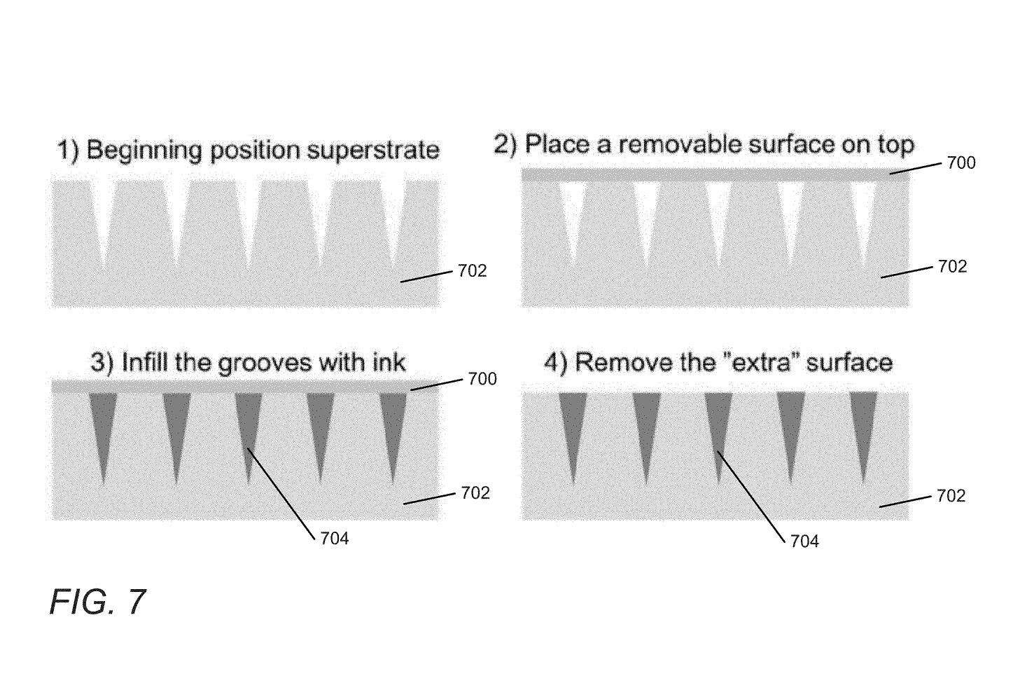

The need for changing the filling profile due to parabolic filling profiles can be circumvented by utilizing different filling methods. One such method includes the use of a removable surface. By closing the triangular shaped channel with a removable surface, the capillary flow can be enhanced. The entire channel can also be filled to prevent the formation of a parabolic filling profile. FIG. 7 conceptually illustrates a filling process utilizing a removable surface in accordance with an embodiment of the invention. As shown, the process includes placing a removable surface 700 on top of a polymer layer 702. The removable surface 700 can be a glass slide or any other surfaces. In many embodiments, the removable surface 700 is rendered hydrophilic to enhance the capillary flow to facilitate the filling process. After infilling the channels with ink 704, the surface can then be removed.

Another alternative method for infilling the grooves includes the use of electroplating. In many embodiments, electroplating can be used the core of a core-outer layer ETC construction. In such embodiments, an outer layer can first be formed using capillary flow, and electroplating can be used to form the core. Using this fabrication process, the outer layer can be formed with a material, such as silver, that results in a highly reflective surface (allowing for the ETCs to redirect incoming light and attaining high optical transparency), and the core can be formed with a good conductive material, such as copper. The core material can also be selected to provide support for the structure, allowing for a higher tolerance of mechanical stress and the ability to retain the structure's original shape. The composite can be more inexpensive to manufacture compared to an ETC made entirely of silver while maintaining sufficient performance standards. As can readily be appreciated, any of a variety of materials can be plated and utilized with the electroplating process. FIG. 8 conceptually illustrates an electroplating process to fill the grooves of the polymer layer of a superstrate in accordance with an embodiment of the invention. In the illustrative embodiment, the polymer layer 800 is infilled with a thin layer of silver 802. The core 804 is then formed with copper via electroplating. As can readily be appreciated, other materials besides silver and copper can be used as appropriate depending on the given application.

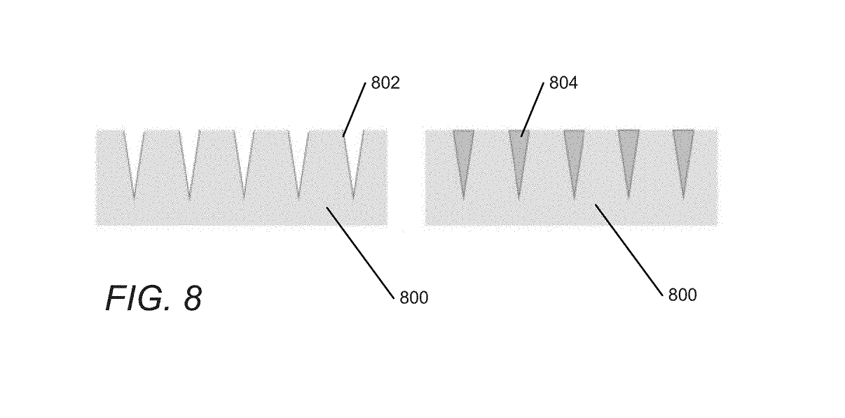

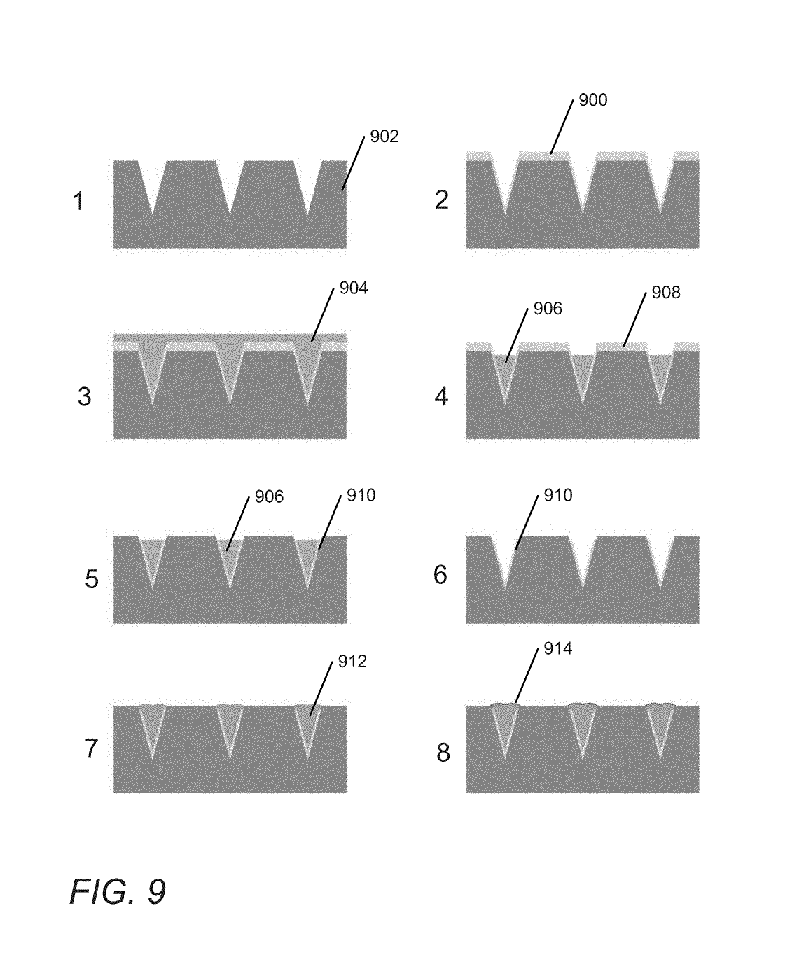

Another alternative method for infilling of the grooves is depicted in FIG. 9. Instead of using silver ink and capillary infill, this approach includes the use of a vacuum deposition process, such as sputtering or evaporation, to deposit a thin layer of metal 900, such as but not limited to silver, over the surface of the polymer layer 902 of the ETC superstrate as a seed layer for electroplating. To confine the metal to within the triangular grooves, the metallic seed layer can be removed from the other areas of the ETC superstrate. A polymer resin 904, such as a positive photoresist, can be spin-coated over the covered polymer layer 902 and heated above its reflow temperature to planarize the surface of the resin layer. Then, the superstrate can be placed in a solution that etches the polymer resin. In the case of photoresist, this can be achieved by flood-exposing the resist and placing it in an appropriate developer solution. The duration of this step can be chosen such that the photoresist is removed from the ETC superstrate surface except within the grooves 906. Then, the ETC superstrate can be placed in a metal etchant solution to remove the metal from unmasked areas 908, leaving the reflective metallic layer only on the sidewalls of the grooves 910. The remaining polymer resin 906 can be removed by placing it into a suitable etch solution or remover. The remaining volume of the grooves can be infilled with metal 912 via electroplating. Various metals can be used with such processes. For example, copper can be selected due to its low cost (vs. silver) and high conductivity. An additional capping layer 914, such as but not limited to silver, can be applied in an additional electroplating step if needed as a diffusion barrier or to provide a suitable surface for bonding the ETC superstrates to a solar cell's existing contacts. Because this fabrication approach does not rely on the infilling of the grooves by capillary forces, it can be scaled to arbitrarily large areas with a high degree of uniformity.

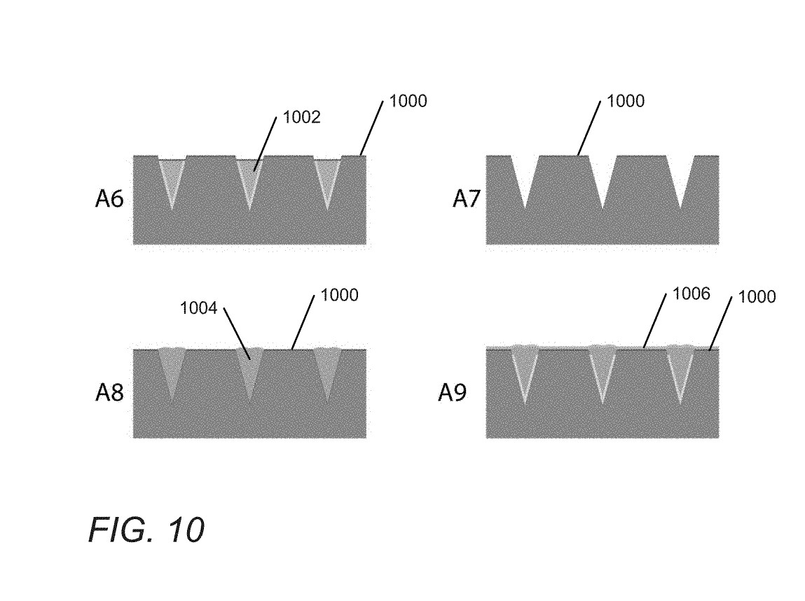

A variation on the approach described above is shown in FIG. 10. Following the etch-back of the metal, a thin dielectric layer 1000 can be deposited onto the exposed polymer surface of the ETC superstrate. Then, the polymer resin mask 1002 can be removed as described above, and the grooves are infilled with metal 1004 via electroplating. Finally, a transparent conductive layer 1006 can be applied to the ETC superstrate surface as described previously. The thin dielectric layer 1000 serves as an antireflective layer between the transparent conductive layer (e.g., ITO) and the ETC superstrate polymer (e.g., PDMS). The dielectric contrast between these materials is typically responsible for several percent reflectance loss in many thin-film solar cells such as perovskite solar cells. As such, the inclusion of an antireflective layer can improve the efficiency of the solar cell.

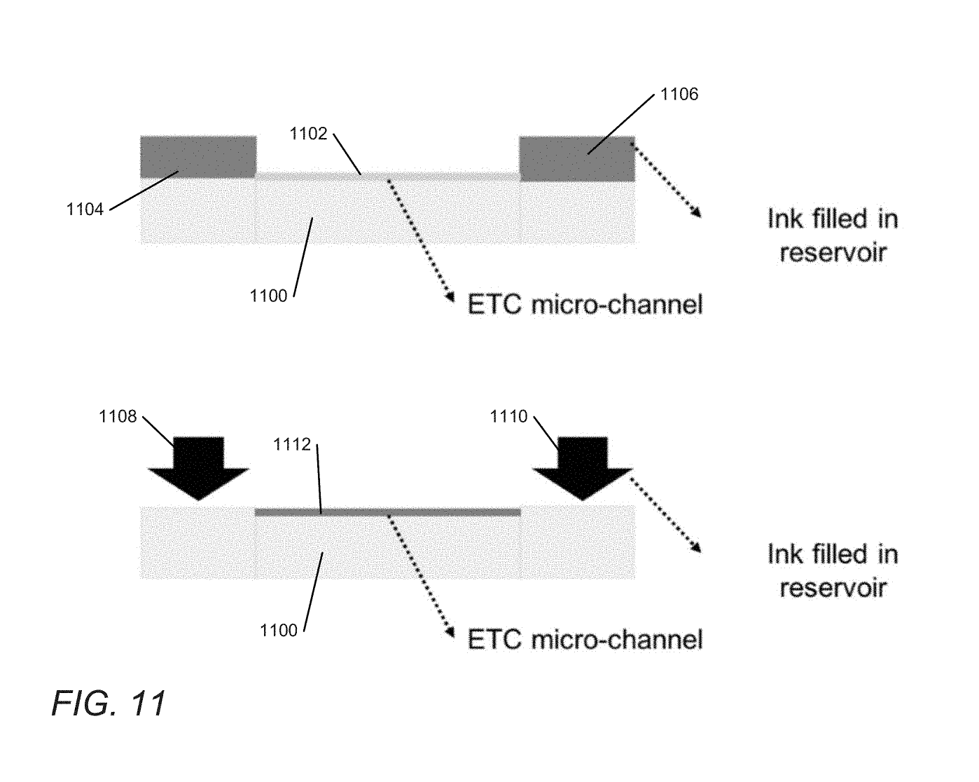

Another alternative method for infilling of the grooves includes the use of pressure to distribute the conductive ink throughout the grooves. Substrates used in this filling process can be prepared with larger busbar areas that can be infilled with ink. Afterwards, pressure can be applied to the softer busbar areas on the side of the ETC superstrate. The applied pressure can cause the ink to flow throughout the micro-channel. Such a process is conceptually illustrated in FIG. 11. As shown, the superstrate 1100 contains an unfilled micro-channel 1102. Reservoir areas 1104, 1106 can be filled with ink. Afterwards, pressure (indicated by arrows 1108, 1110) can be applied to distribute the ink to fill the micro-channel 1112. handle

Another approach for the infilling of the grooves includes processing the polymer such that the surfaces of the grooves is hydrophilic while the remaining surfaces of the polymer is hydrophobic. This can be achieved using various techniques known in the art. After the polymer is processed, ink can be deposited to cover and fill at least the grooves. Any of a variety of deposition techniques can be used, including but not limited to inkjetting and spraying. The ink on the remaining surfaces of the polymer can then be removed using any of a variety of different techniques, such as but not limited to doctor blading processes.

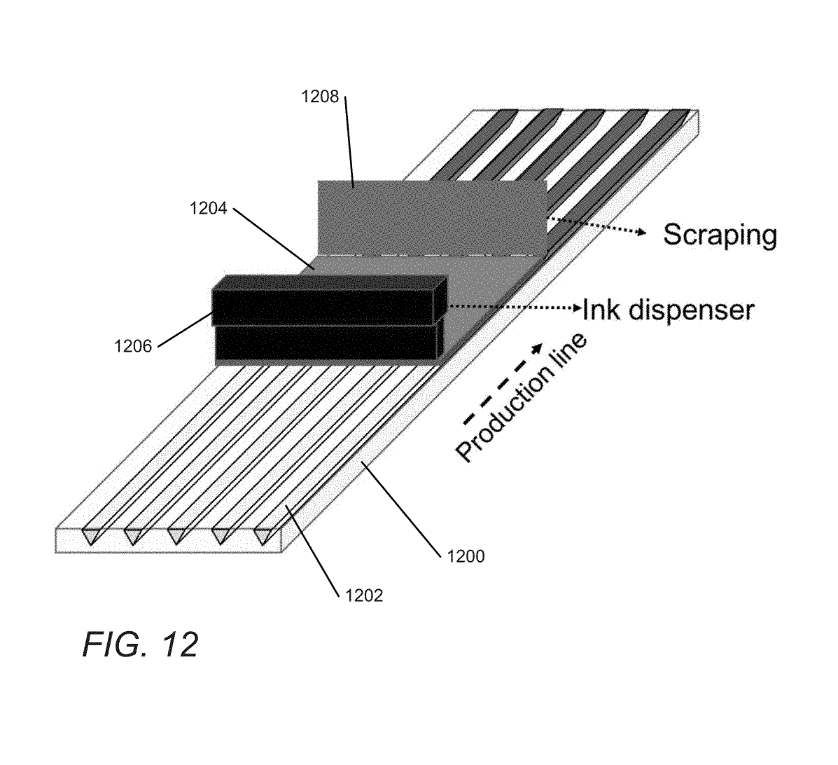

FIG. 12 conceptually illustrates an infilling process utilizing doctor blading techniques in accordance with an embodiment of the invention. As shown, the process starts with a polymer 1200 with embossed triangular shaped grooves 1202. Afterwards, the optical film substrate (polymer) 1200 can optionally undergo surface treatment to render the grooves hydrophilic and the intermediate spacing (flat portion of the polymer in between the grooves) hydrophobic. This surface treatment can be performed via (for example) oxygen plasma but is not limited to oxygen plasma, by covering the film such that the grooves are only exposed to the oxygen plasma. This will result in the fact that the silver nanoparticle ink has the tendency to go into the grooves rather than staying on the flat surface. Afterwards, silver nanoparticle ink 1204 can be continuously deposited on top of the optical film (polymer substrate with triangular shaped grooves) 1200 via an ink dispenser 1206. In other embodiments, other types of deposition heads and mechanisms can be used. The silver ink will have the tendency to go into the grooves since the surfaces of the grooves have been rendered hydrophilic. Afterwards, the silver ink residue (excess ink) is removed via scraping 1208 the polymer surface. In several embodiments and the excess ink can be collected to be reused, thereby creating a closed loop system. This large-scale manufacturing method allows infilling of the grooves without the need to align the dispensing nozzles, which could be micro-nozzles, with the grooves.

ETC superstrates in accordance with various embodiments of the invention can be formed as a multilayered composite. In many embodiments, a thin layer superstrate with embedded ETCs is constructed on top of a second layer. In some embodiments, the superstrate layer is formed with PDMS while the second layer is formed with EVA. In such embodiments, the PDMS allows for a high annealing temperature in order to reduce the resistance of the conductive ink while the EVA layer allows the superstrates to be manufactured at a lower cost. In such embodiments, the superstrate layer can be formed to be as thin as possible to further reduce cost. As can readily be appreciated, the materials used for the two layers can vary and can depend on the specific requirements of a given application.

In order to make the ETC superstrate compatible with certain solar cell grid designs, a busbar can be integrated into the ETC superstrate. In many embodiments, a single-conductor busbar layout is used. In other embodiments, a multi-conductor busbar layout is used. The busbar conductor(s) can be of any shape, including triangular shaped, such that light incident on the busbar from vertically above the solar cell is reflected directly at the solar cell surface, in the same manner as described for the ETC gridlines.

For a sufficient single-conductor triangular busbar, the size of the busbar will typically be larger than the size of individual ETC gridlines, owing to the greater current carried by the busbar; however, the width of the busbar will typically be smaller than traditional busbars, owing to the high aspect ratio of the triangular bus bar. In some embodiments, the size of the busbar is on the order of several 100s of micrometers. In further embodiments, the busbars are on the scale of 100-300 micrometers in width and 300-900 micrometers in height. Because of the size discrepancy between the smaller ETC conductors and the larger busbar conductors, in some embodiments, the two types of conductors can be fabricated by different methods, for example, the ETC conductors can be fabricated using the capillary silver ink inflow process described above, while the triangular busbar conductor may be fabricated by pressing a triangular-shaped bar of silver-plated copper into the superstrate groove.

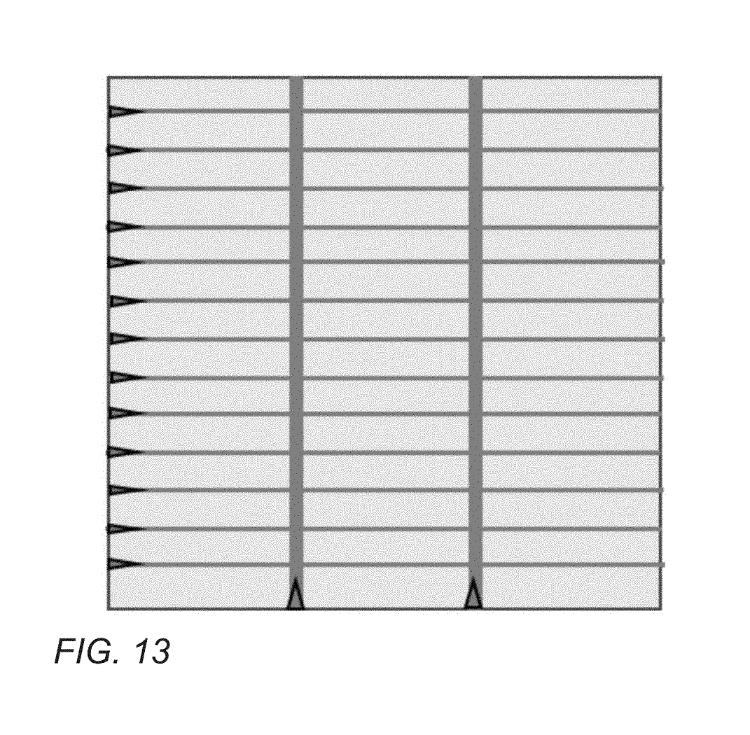

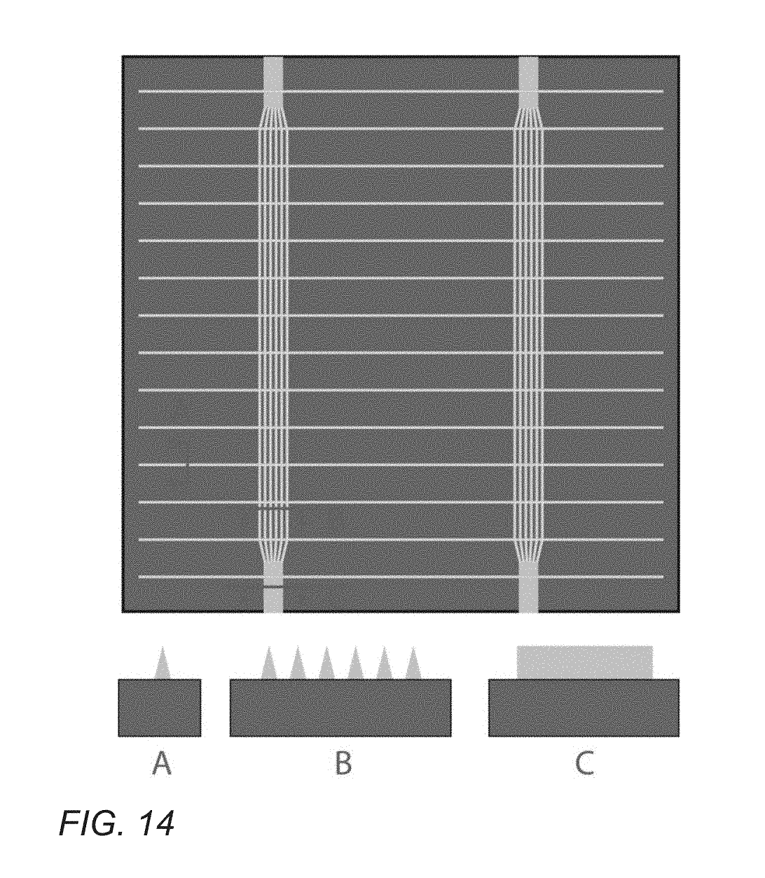

A multi-conductor busbar layout permits the use of smaller busbar conductors, including the case of triangular busbar conductors having similar approximate dimensions as the ETC gridlines. Examples of a single-conductor busbar and a multi-conductor busbar ETC grid pattern in accordance with various embodiments of the invention are conceptually illustrated in FIGS. 13 and 14. In a number of embodiments, the busbar conductors are integrated generally perpendicular to the ETC gridlines. Similar to the formation of the gridlines, the busbar conductors can be fabricated by imprinting the corresponding grooves into the ETC superstrate and infilling the grooves with a reflective, conductive material, essentially creating a grid pattern including ETC gridlines and busbar conductors. Similar to the design of the ETC gridlines, the aspect ratio and spacing of the busbar conductors can be tailored to optimize the energy generation from the solar cell based on the specific requirements of a given application, and can be designed with different spacing or aspect ratio than the ETC gridlines based on the intended orientation of the solar cell with respect to the range of insolation angles throughout the day or year. The number of busbars per cell (typically, two) can also be chosen to suit the needs of the specific application. In several embodiments, one or zero busbar is implemented. In cases where multiple solar cells are to be connected by tabbing wire, as is customary for most wafer-based Si solar cells, the triangular busbar conductors can be connected or joined together to regions on the ETC superstrate having appropriate geometry for bonding to the tabbing wires.

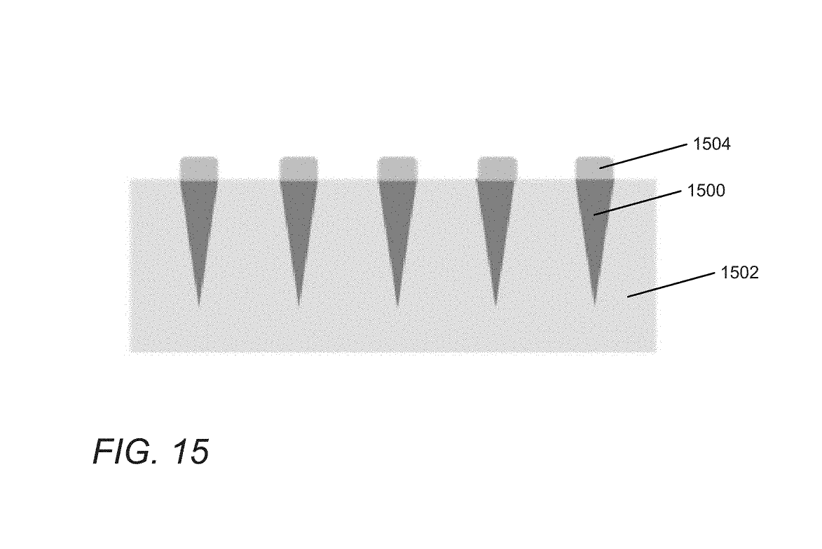

In many embodiments, additional layers and/or materials can be added to the superstrate to change the surface that will be integrated with other structures. In some embodiments, a soldering layer is added to the ETCs. FIG. 15 conceptually illustrates an ETC superstrate with a soldering layer in accordance with an embodiment of the invention. As shown, the ETCs 1500 are embedded within a polymer layer 1502. On top of each ETC is a soldering layer 1504 that can allow for the integration of the ETC superstrate more easily. In some embodiments, a layer of ITO is added on top of the ETCs. The ITO layer can from a good lateral charge transport layer when integrated, such as when integrating with perovskite solar cells. In other embodiments, a copper buffer layer can be added. As can readily be appreciated, the type of added surface can depend on the specific requirements of a given application.

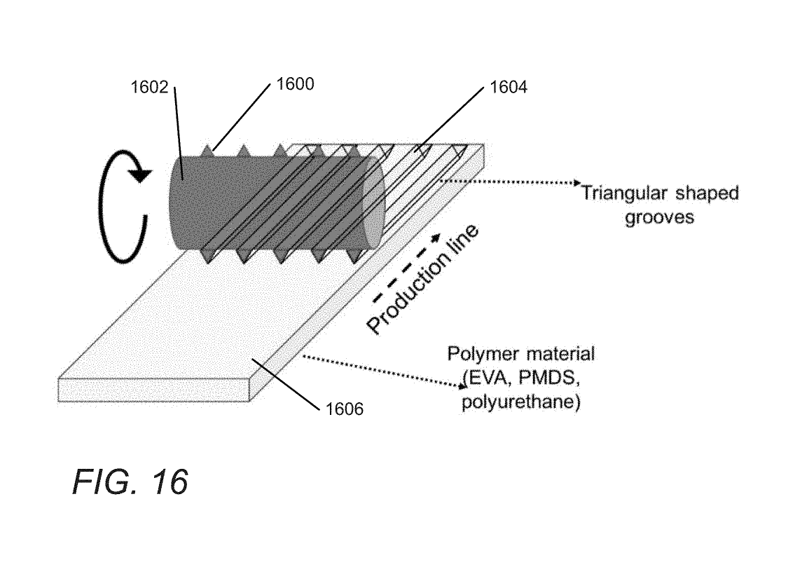

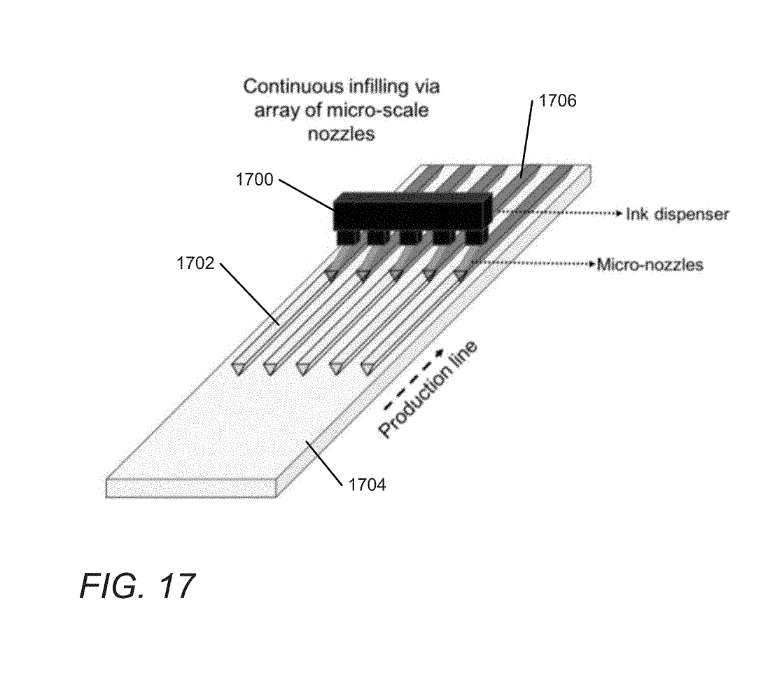

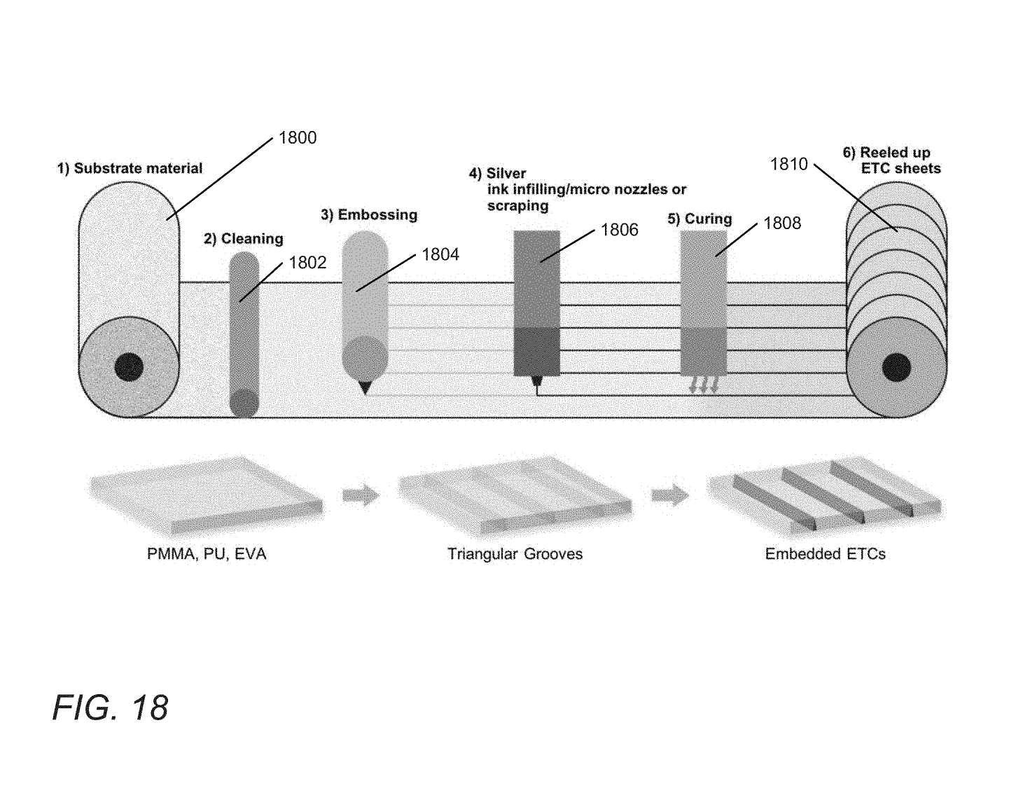

In addition to the methods described above, ETC superstrates in accordance with various embodiments of the invention can be fabricated using techniques compatible with large-scale fabrication. In many embodiments, the fabrication includes the mechanically removing material from a polymer sheet to form triangular grooves. The removal process can be achieved in a variety of different ways. In some embodiments, the removal process is performed using laser(s). In other embodiments, a diamond scribe is used to remove the material. In these embodiments, the process can be performed over a large area, allowing for high throughput manufacturing. FIG. 16 conceptually illustrates a cutting process for large-scale fabrication of ETC superstrates in accordance with an embodiment of the invention. In the illustrative embodiment, triangular shaped cutting blades 1600 are mounted on a roll 1602. As the roll 1602 rolls, triangular shaped grooves 1604 are formed in the polymer material 1606. After formation of the grooves, the grooves can be filled with conductive ink, similar to the processes described above. In many embodiments, the grooves are continuously filled with conductive ink via an array of micro-nozzles. The micro-nozzles can also be aligned and/or follow the cutting tool to simplify the issue of alignment. A filling process for large-scale fabrication of ETC superstrates in accordance with an embodiment of the invention is conceptually illustrated in FIG. 17. As shown, the process includes the use of an array of micro-scale nozzles 1700 to fill triangular grooves 1702 within a polymer sheet 1704 with conductive ink 1706. This process can be performed in conjunction with various other manufacturing steps. FIG. 18 conceptually illustrates an overview of an ETC superstrate manufacturing line in accordance with an embodiment of the invention. As shown, the process includes starting with a sheet of substrate material 1800, typically a transparent polymer. A cleaning apparatus 1802 can be used to prepare the substrate 1800, and an embossing tool 1804 can follow the cleaning apparatus 1802 to form the desired grooves within the substrate 1800. A dispensing head 1806, such as but not limited to micro-nozzles, can be used to infill the grooves with a conductive material. Although FIG. 18 illustrates the specific use of a dispensing head, any of the infilling methods as described above can be used in conjunction with a manufacturing line. A curing element 1808 can be used to cure the dispensed material, and an ETC superstrate sheet 1810 can be formed.

### Integration of ETC Superstrates

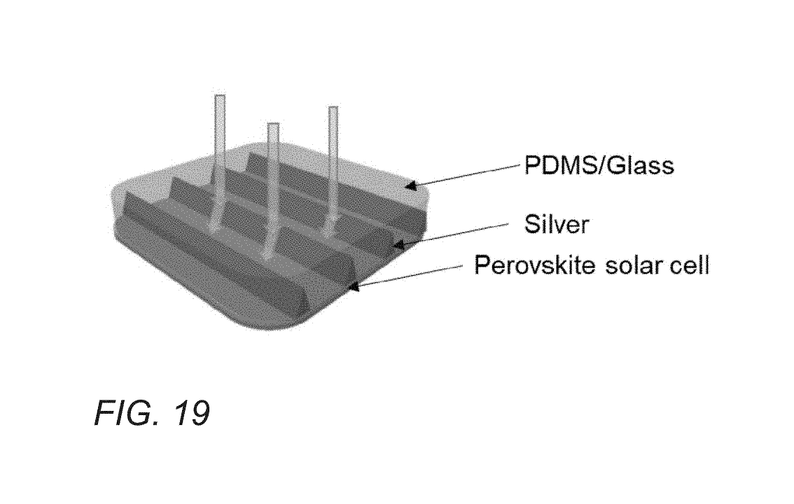

ETC superstrates in accordance with various embodiments of the invention can be implemented in a variety of solar cell applications. In many embodiments, the ETC superstrate is integrated with a perovskite solar cell. FIG. 19 conceptually illustrates a schematic of a perovskite solar cell with an ETC superstrate in accordance with an embodiment of the invention. In the illustrative embodiment, the superstrate is composed of soda-lime glass with a thin (˜40 μm) layer of polydimethylsiloxane (“PDMS”) that features triangular cross-section microscale grooves. As shown, the superstrate is integrated with a standard perovskite solar cell. In many embodiments, the grooves are infilled with a conductive silver ink and subsequently coated by a thin (˜30 nm) ITO layer such that high lateral conductivity (<5 Ω/sq) can be achieved without altering the surface properties compared to that of standard perovskite superstrates. Due to the reduction of the ITO thickness, parasitic absorption can be greatly reduced and antireflection properties can be optimized, leading to an increase in short-circuit current density of more than 1 mA/cm². High lateral conductivity can be obtained by spacing the triangular silver lines closely (˜80 μm distance). Whereas densely spaced grid fingers would normally cause excessive shading losses, the triangular cross-sections and high aspect ratios as shown in the illustrative embodiment serve to reflect most or all incident light to metal-free areas of the superstrate. In some embodiments, an effective transparency of greater than 99% can be achieved. In a number of embodiments, FACsPbI₃ perovskite solar cells were fabricated with thin ITO and showed improved external quantum efficiency with an average integrated short-circuit current increase of more than 1 mA/cm². In several embodiments, the design of the device was guided using computational modeling of optical and electrical properties.

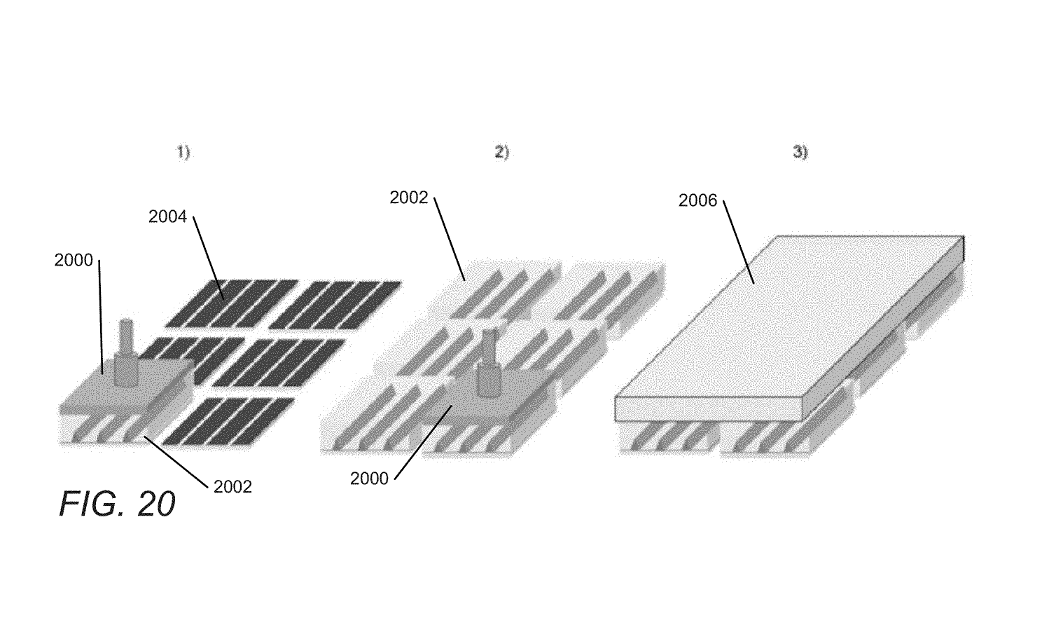

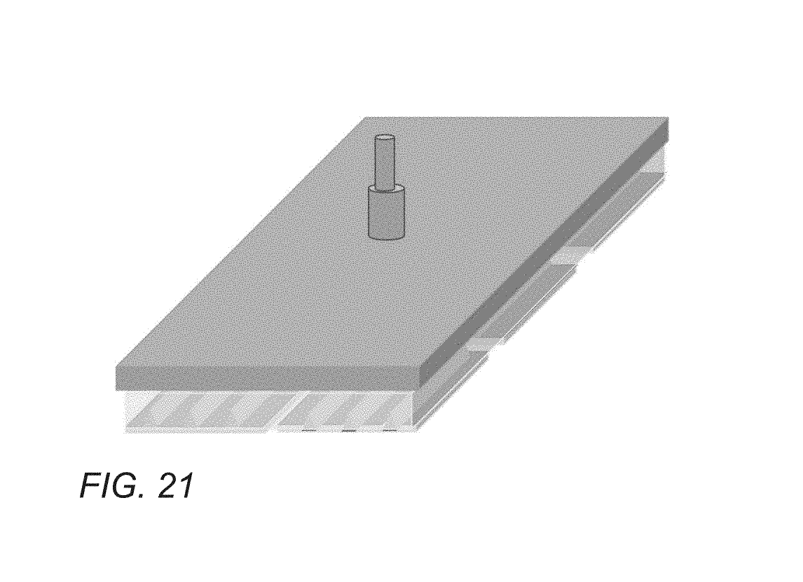

In many embodiments, the ETC superstrate is integrated with a solar cell having existing contacts. In such cases, the integration process can include an alignment step. Alignment can be performed using several methods. In some embodiments, an alignment arm, which can be computer controlled, is used to position the ETC superstrate to align with the solar cell. In other embodiments, the alignment system positions the solar cell to align with the ETC superstrate. After the integration of individual solar cells with TC superstrates, a lamination layer can be added to hold the modules together while providing protection from environmental disturbances. FIG. 20 conceptually illustrates the integration of individual solar cells along with the addition of a lamination layer in accordance with an embodiment of the invention. As shown, an alignment system 2000 aligns individual ETC superstrates 2002 with solar cells 2004. Afterwards, a lamination layer 2006 is added on top of the modules, holding them in place relative to each other. In many embodiments, a single ETC superstrate can span across multiple solar cells. FIG. 21 conceptually illustrates a single ETC superstrate layer placed on top of multiple solar cells in accordance with an embodiment of the invention. Depending on the application, such embodiments no longer includes an additional polymer layer, and the ETC superstrate can effectively function an encapsulant layer. The ETC superstrate can also be formed to have an appropriate thickness to compensate for the lack of a lamination layer.

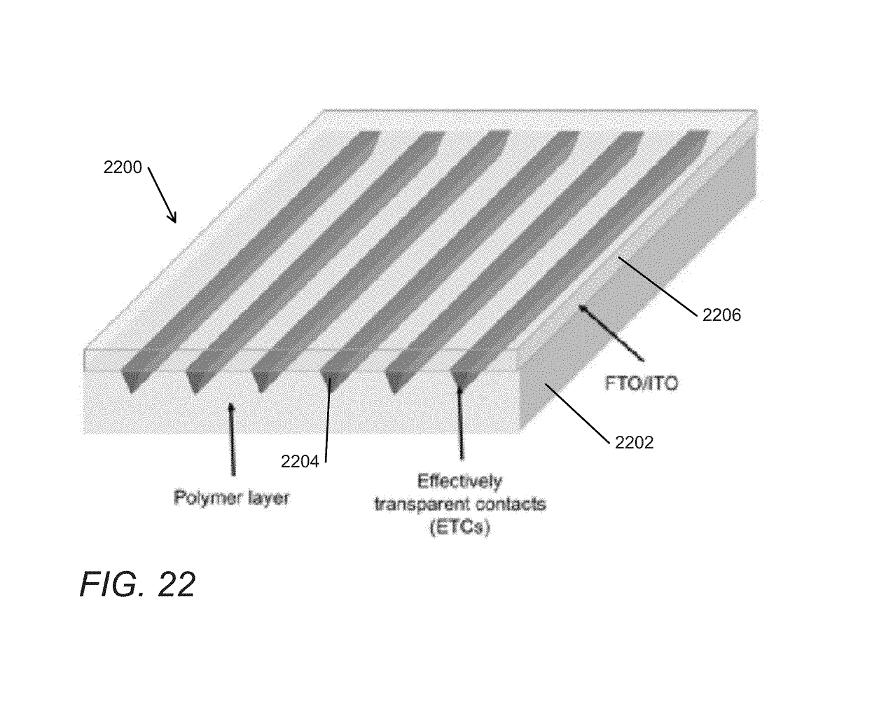

ETC superstrates in accordance with various embodiments of the invention can be formed with a layer of TCO or transparent conductors in general. FIG. 22 conceptually illustrates an ETC superstrate incorporating a layer of TCO in accordance with an embodiment of the invention. As shown, the superstrate 2200 includes a polymer layer 2202 with embedded ETCs 2204. The superstrate 2200 also includes a layer of fluorine doped tin oxide (“FTO”)/ITO 2206. This composite can form a superstrate in accordance with various embodiments of the invention without altering the surface properties found in conventional superstrate used for thin-film fabrication (e.g., cadmium telluride, copper indium gallium diselenide, and amorphous thin-film silicon or perovskite solar cells). In many embodiments, the TCO layer is much thinner than the conventional TCO layer, which can reduce the parasitic absorption in the TCO layer. Furthermore, the cost of the manufacturing process is also reduced due to the reduction in material. In some embodiments, the TCO layer is replaced by a polymer layer embedded with silver. Afterwards, the absorber layer can be deposited on top of the superstrate to form a thin film solar cell (e.g., a cadmium selenium telluride layer can be deposited on top of the thin TCO layer of the ETC superstrate via vapor transport deposition). This same process and technique can also be used for the integration of ETC superstrates with perovskite and other thin-film technologies.

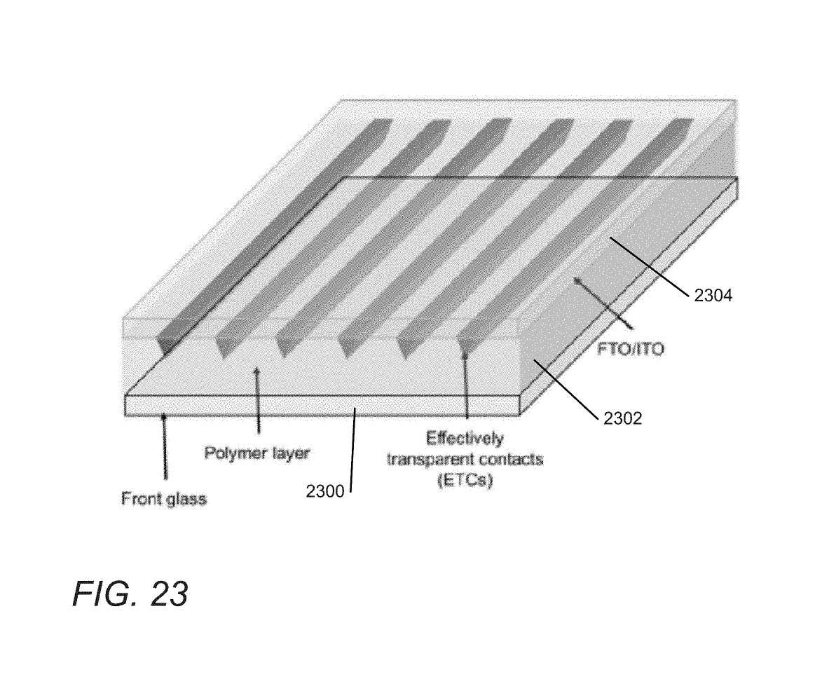

In addition to the integration of ETC superstrates as a replacement for the top contact/encapsulant material, ETC superstrates can also serve as a starting material on which a solar cell can be grown. In many embodiments, the ETC superstrate can be formed on top of the front glass of the solar module. For example, for a perovskite solar cell, the ETC superstrate can be placed on top of a glass substrate, and the perovskite solar cell stack can then be integrated on top of the superstrate. FIG. 23 conceptually illustrates an ETC superstrate with a top TCO layer placed on top of the front glass of a thin-film solar module in accordance with an embodiment of the invention. As shown, the starting material on which the thin-film solar cell is grown can be the front glass 2300 with the ETC superstrate 2302 and thin TCO layer 2304. With this structure, the parasitic absorption in the TCO layer of conventional thin-film applications is highly reduced.

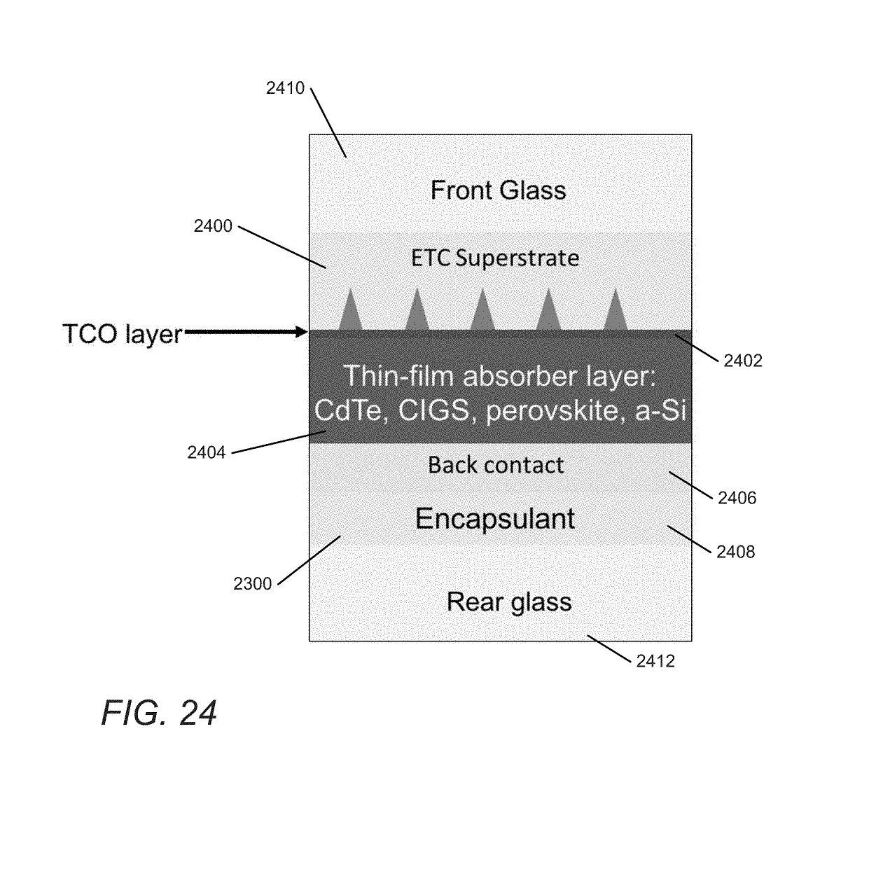

FIG. 24 conceptually illustrates an ETC superstrate integrated with a thin-film solar cell in accordance with an embodiment of the invention. As shown, the ETC superstrate 2400 is in contact with a TCO layer 2402, which is in contact with a thin-film absorber layer 2404 (such as but not limited to CdTe, CIGS, perovskite, a-Si (amorphous silicon)). Also shown are the back contact 2406 and encapsulant layer 2408. The entire module is sandwiched between two layers of glass 2410, 2412. Although FIG. 24 illustrates a specific integration of an ETC superstrate, any of a variety of integration schemes can be utilized as appropriate in accordance with a given application.

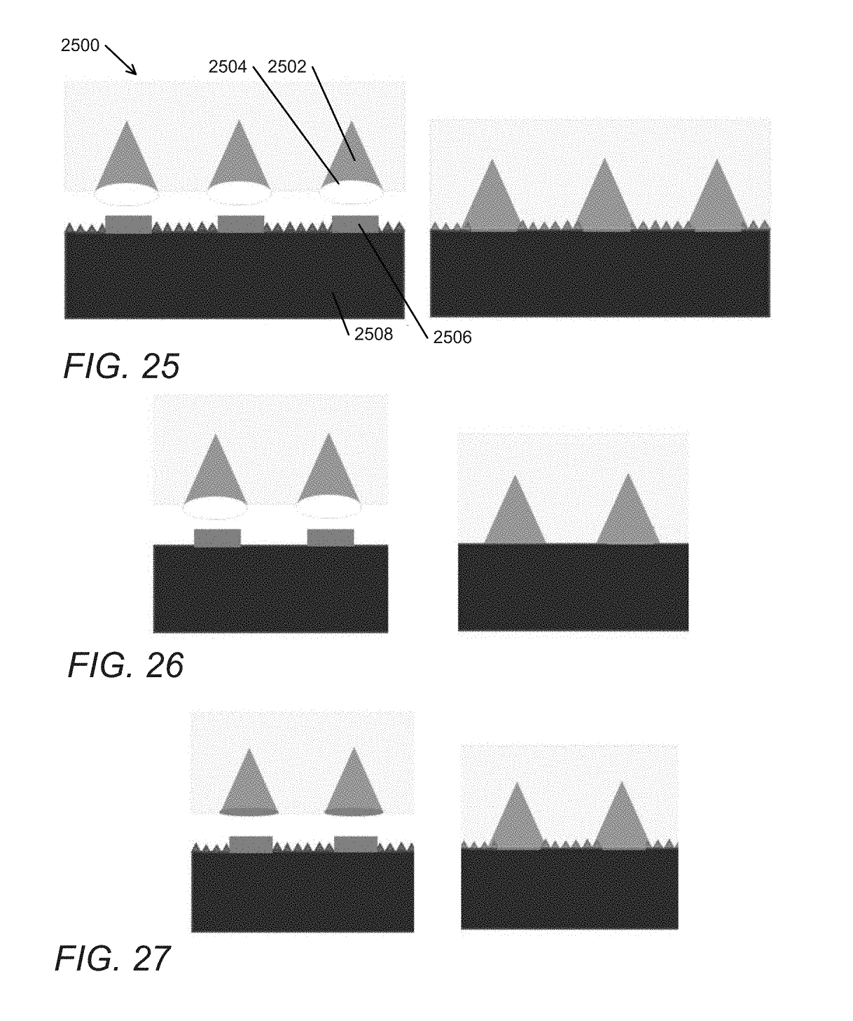

In embodiments where the ETC superstrate is integrated with a silicon PERC solar cell, the ETCs can form an electrical contact with the existing contacts on the solar cell. In such cases, the parabolic filling profile as discussed above can be beneficial since the space created by the parabolic curve can be filled with the existing contact. FIG. 25 conceptually illustrates the use of a parabolic filling profile for the integration of an ETC superstrate on top of existing contacts on a silicon PERC cell in accordance with an embodiment of the invention. As shown, the ETC superstrate 2500 contains ETCs 2502 having parabolic surfaces 2504. The existing contacts 2506 can fill the void created to allow for the integration of the ETC superstrate with the silicon PERC cell 2508. This integration process can similarly be applied to III-V solar cells, although the adhesion might not perform as well since these cells are typically planar without any texturing (FIG. 26). As discussed above, a soldering layer can also be used to provide a better electrical connection and adhesion between the ETCs and the existing contacts on the solar cell (FIG. 27).

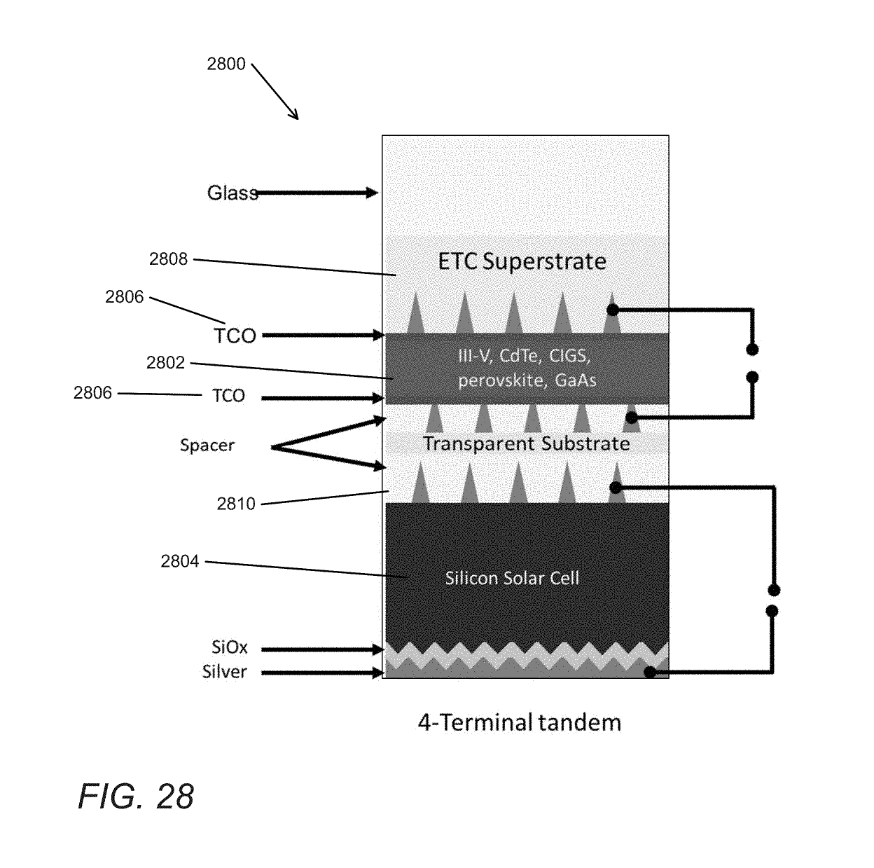

In some embodiments, the ETC superstrate is integrated in a tandem solar cell architecture. FIG. 28 conceptually illustrates a tandem solar cell utilizing ETC superstrates in accordance with an embodiment of the invention. As shown, the tandem solar cell 2800 utilizes a 4-terminal configuration and incorporates a perovskite or III-V cell 2802 top of a sub silicon solar cell 2804. In the illustrative embodiment, the top cell 2802 includes TCO layers 2806. By integrating an ETC superstrate 2808, the TCO layer thickness can be reduced, thereby allowing more sunlight to reach the solar cell device. In many embodiments, the TCO layer thickness is reduced form the typical 200 nm to below 100 nm. Without the integration of the ETC superstrate 2808, reduction of the TCO layer thickness would result in increased series resistance, which would not allow for sufficient charge extraction. In some embodiments, a dielectric spacer is implemented underneath the ETC Superstrate to obtain optimal light management. In further embodiments, the dielectric spacer is made from high refractive index and non-absorbing material. Underneath the dielectric spacer, an ETC superstrate 2810 is integrated as top contact for the silicon solar cell 2804. In a number of embodiments, this ETC superstrate 2810 is aligned with the existing contacts on the silicon solar cell 2804.

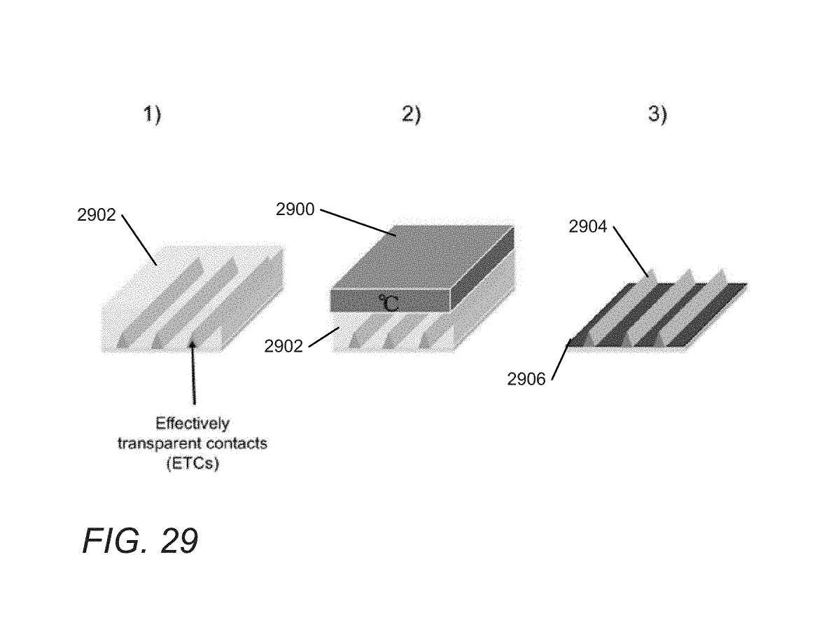

In many embodiments, the ETC superstrate can be integrated such that only the ETCs remain. In such embodiments, the ETC superstrate is first placed on top of the solar cell. A polymer removal process, such as through the use of a solvent or the application of heat, can be performed to remove the polymer layer, leaving behind the ETCs. FIG. 29 conceptually illustrates the use of an ETC superstrate as a sacrificial mold in accordance with an embodiment of the invention. In the illustrative embodiment, a heat source 2900 is used to remove the polymer layer 2902 of material, leaving behind ETCs 2904 on top of a solar cell 2906. In such cases where the polymer can be removed when heated, the metal ETCs can be made of silver paste and can fire through the silicon nitrate layer and form an ohmic contact while the sacrificial polymer mold is removed. Using this integration method, conventional flat metal contacts can be replaced entirely with the ETCs, removing the need of an alignment step.

In addition to the many different ways ETCs can be integrated with various applications, these integration schemes can occur during the module manufacturing process. As discussed above, ETC superstrates can serve as a replacement for EVA module encapsulation. In such cases, the ETC superstrate simply replaces the encapsulant during the solar module manufacturing process. In some embodiments, the ETC superstrate is introduced in an intermediate step prior to module encapsulation. ETC superstrates can be implemented to align individually to solar cells during or after tabbing. In some embodiments, ETC superstrates can be implemented in a whole-module encapsulation process. In a number of embodiments, module-size superstrates can be aligned with busbar-less solar cells in a shingled configuration and laminated in a single step.

### Transmission and Reflection Measurements of ETC Superstrates

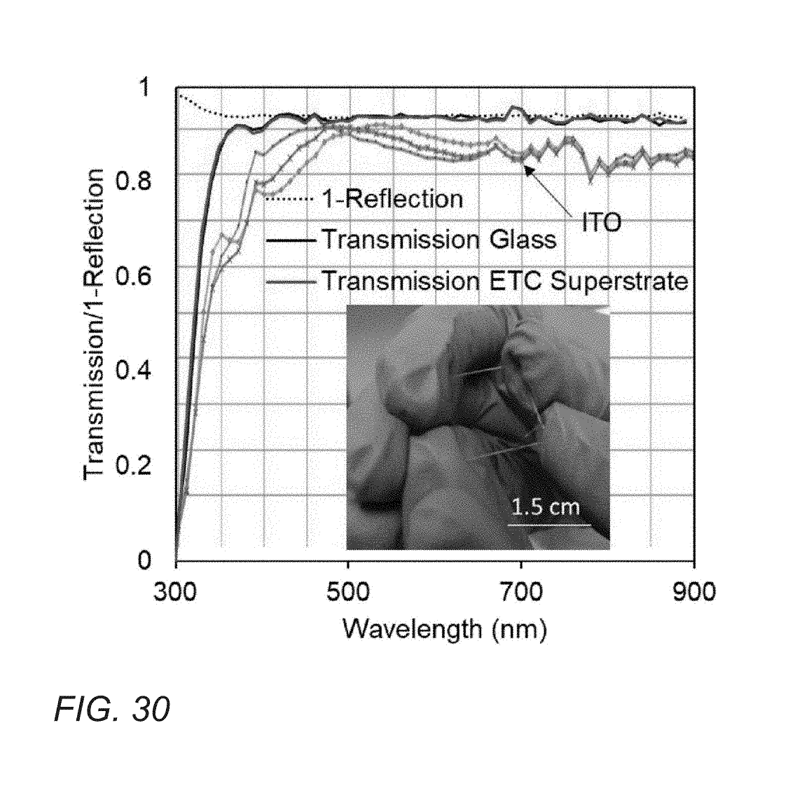

Wavelength-dependent transmission and reflection measurements of ETC superstrates can be performed using a chopped and monochromated white light source. Transmitted and reflected light can be directed onto a photodiode connected to a lock-in amplifier. The direct photodiode signal can be used as reference for the measurements. FIG. 30 conceptually shows the transmission of a bare glass superstrate and an ETC superstrate as well as 1-reflection of a glass superstrate before depositing ITO in accordance with an embodiment of the invention. The inset shows a picture of an ETC superstrate. As shown, the transmissions of bare glass and ETC superstrates are similar. A quantitative comparison demonstrates more than 99% transparency of the ETC superstrate compared to the bare glass. Absorption between 300 nm and 400 nm can be attributed to absorption within the soda-lime glass. In a number of embodiments, the superstrates can be fabricated without soda-lime glass in order to obtain lightweight, flexible, and less absorbing superstrates. In the illustrative embodiment, both transmission measurements were adapted to account for a normalization error during the measurement that does not influence the relative result.

### External Quantum Efficiency Dependence on Indium Tin Oxide Thickness

Computational optical simulations and experiments can be performed to investigate the effects of decreased indium tin oxide thickness on the external quantum efficiency of perovskite solar cells. In many embodiments, simulations and experiments were performed on solar cells with a soda-lime glass superstrate, ITO with different thicknesses, 10 nm NiO, 375 nm Formamidinium cesium lead iodide (FACsPbI₃) perovskite, 10 nm phenyl-C61-butyric acid methyl ester (PCBM), and 300 nm silver. Optical simulations can be performed using appropriate software, such as PV Lighthouse's Module Ray Tracer. Complex refraction indices of the individual materials can be obtained by ellipsometry or by transmission/reflection measurements. The wavelength-dependent absorption within the perovskite layer can be simulated and weighted with the AM 1.5G solar spectrum. Integrating over the wavelength can lead to the generated photocurrent density.

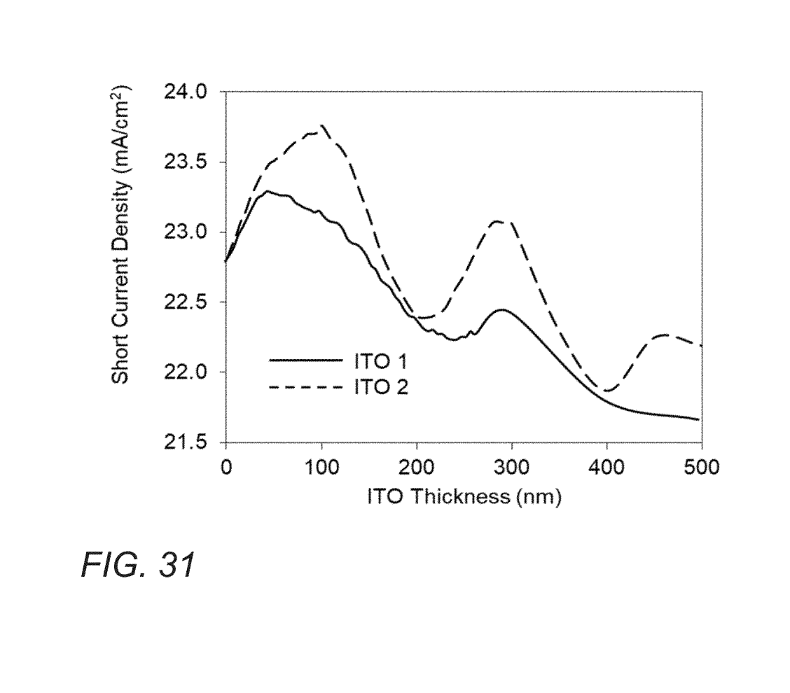

In many embodiments, the internal quantum efficiency of the device is assumed constant over the whole wavelength regime. FIG. 31 shows the simulated short circuit current with respect to the thickness of ITO in accordance with an embodiment of the invention. In the illustrative embodiment, two different types of ITO were considered. ITO2 was deposited by researchers at Arizona State University, and ITO1 was deposited by Colorado Concept Coatings LLC. As shown in FIG. 31, changing the thickness of both ITOs leads to local maxima and minima in short circuit current that originate from thin film interference. The local maxima become smaller towards thicker ITO due to parasitic absorption.

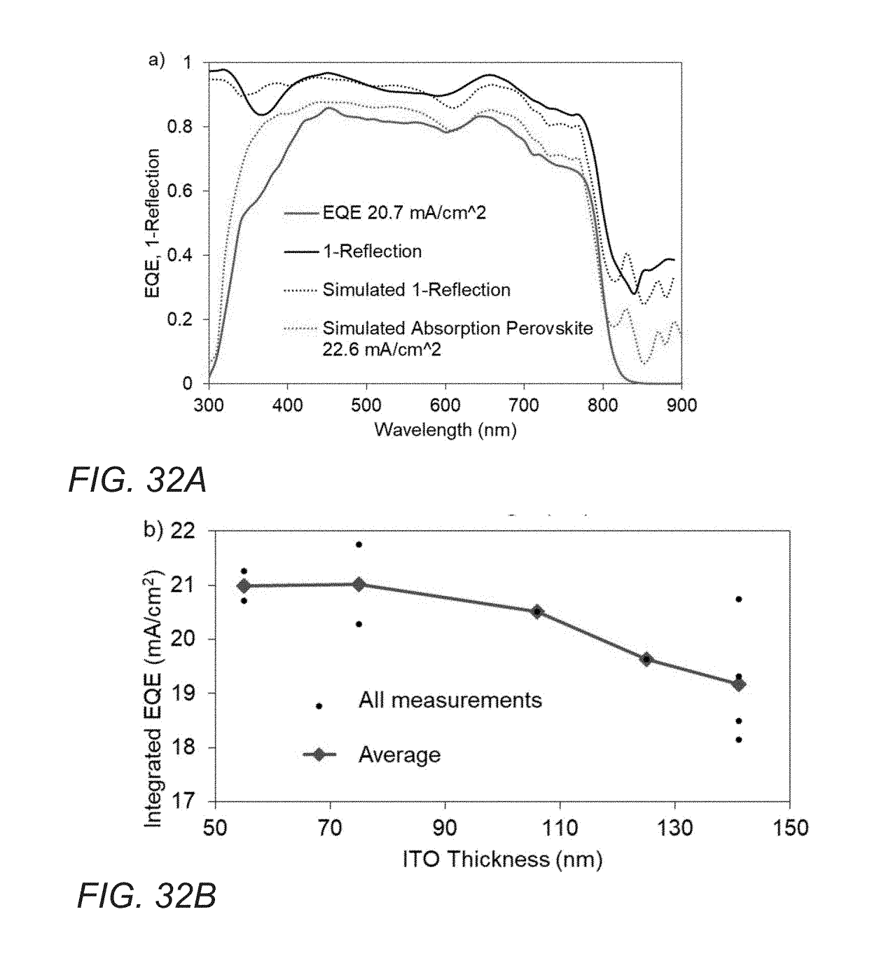

The external quantum efficiency (“EQE”) and the reflection can also be measured on the above-described FACsPbI3 perovskite solar cells with different ITO thicknesses. FIG. 32A shows a comparison of the measured data with the simulated data for an ITO thickness of 140 nm in accordance with an embodiment of the invention. The measured 1-reflection data is shown in the top solid curve while the simulated data is presented in the top dashed curve. As shown, the simulated curves follow the experimental curves closely and capture most features correctly. In the illustrative embodiment, simulations underestimate reflection between 350 nm and 400 nm, which most likely resulted from an error in optical data collection. The bottom solid curve in FIG. 32A shows the measured EQE while the bottom dashed curve presents the simulated absorption within the perovskite layer. As shown, the measured EQE is lower than the simulated absorption, but both curves show similar results overall.

Between 350 nm and 400 nm, the discrepancy can be explained by the underestimated reflection loss. Furthermore, it is likely that an internal quantum efficiency lower than 1 is causing the difference in other wavelength regimes. FIG. 32B shows the integrated EQE of perovskite cells with different ITO thicknesses ranging from 55 nm to 141 nm in accordance with an embodiment of the invention. The black dots show the measurement results while the curve follows the average result. As a general trend, the integrated EQE becomes lower with increased ITO thickness and experiences a maximum between 55 nm and 75 nm, which is consistent with the computational results.

### Effective Transparency, Light Trapping, and Sheet Resistance

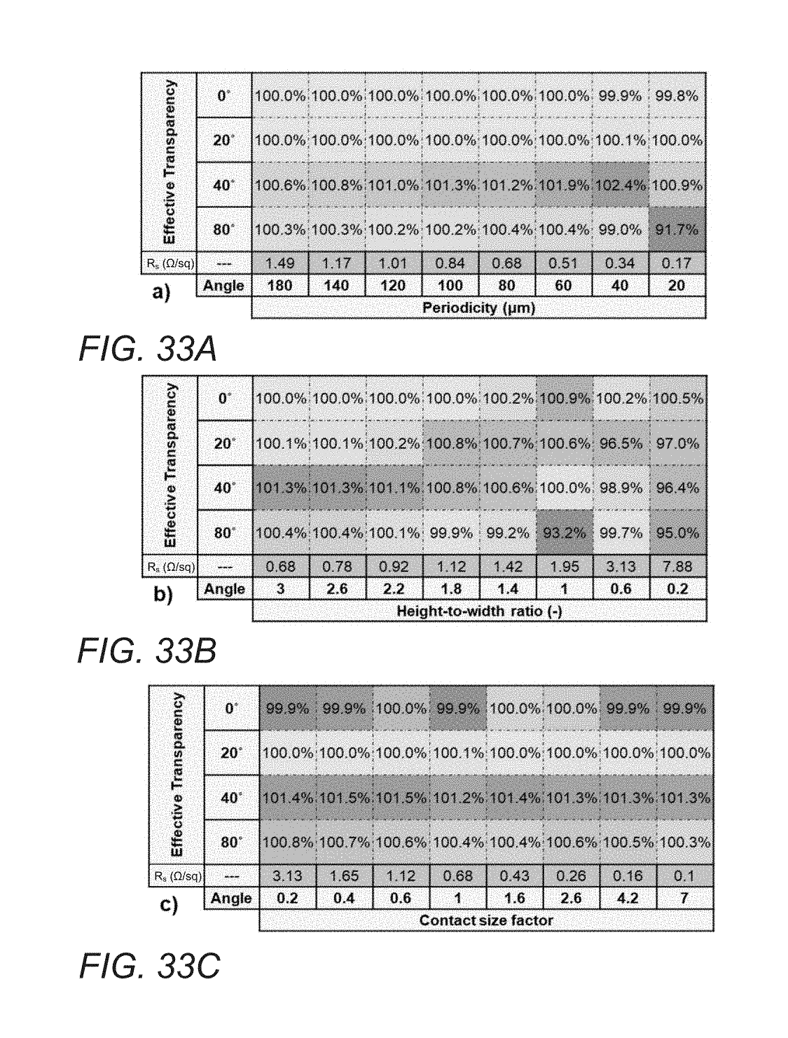

Optical simulations can be performed in order to quantify the effective transparency and light trapping properties of ETC superstrates depending on the geometry of the ETCs. Similar simulation software and materials as described in the previous section can be used. In many embodiments, triangular cross-section silver lines were added within the glass superstrate. In further embodiments, a 60 nm thin layer of ITO1 was used in addition. The light absorption within the perovskite layer can be determined and weighted with the solar spectrum. FIG. 33A-33C show the change in absorption upon integration of ETCs with different geometries in accordance with an embodiment of the invention. In the illustrative embodiment, 100% corresponds to no change compared to a cell without ETCs but otherwise identical layer stack. Values below 100% correspond to relative losses and values beyond 100% correspond to relative gains enabled by improved light-trapping.

FIG. 33A shows the effective transparency of the superstrate as a function of angle of incidence of the incoming light and of the finger spacing. As shown, for almost all spacing, the effective transparency stays relatively at 100%. At small spacing and large angles, a significant decrease of absorption due to multiple reflections on the fingers can be observed. At shallower angles however, reflection directly into the cell leads to a 100% or even larger transparency, where the absorption above 100% can be attributed to light trapping effects.

FIG. 33B shows the effective transparency of the front metal grid as a function of angle of incidence of the incoming light and of the finger height-to-width ratio. For each angle of incidence, a local maximum in transparency can be observed, after which the transparency significantly decreases. As shown, the maximum occurs at higher ratios for increasing angles of incidence. The maximum can be caused by the interplay of two effects: an increase in absorption with increasing height-to-width ratio due to more redirection towards the cell surface and an increase in absorption with decreasing height-to-width ratio due to increased path length through the cell.

FIG. 33C shows the effective transparency of the front metal grid as a function of angle of incidence of the incoming light and contact size factor. Contact size factor can be defined as the magnitude of all geometrical aspects of the contacts (spacing, height, width) as compared to the “standard” contact (defined as height=15 μm, width=5 μm & spacing=80 μm). Thus, increasing the contact size factor means increasing the size of the contacts while keeping the shape and shading constant. No significant deviations can be observed over the full range of size factors. As before, an increase in absorption at an incident angle of 40° due to light trapping can be observed. Note, however, that the method used for the optical simulation in the illustrative embodiment was based on ray optical light propagation through the contact structure, and therefore, the results for structures with contact size factor smaller than 0.6 might not be accurate as demonstrated earlier.

Furthermore, the sheet resistance of superstrates with the same ETC geometries as used for the optical studies can be calculated. An ink conductivity of 6 μΩ cm can be used. A conductivity of 195 μΩ·cm was measured for ITO1, which at 60 nm thickness corresponds to a sheet resistance (RS_ITO) of 32.5 Ω/sq. The ETC sheet resistance (RS_ETC) can be calculated as described previously, and the overall sheet resistance (RS) can be determined by: RS=(RS_ETC×RS_ITO)/(RS_ETC+RS_ITO). FIG. 33A-33C illustrate these results. It can be seen that for all geometries of ETCs, the sheet resistance of the superstrate was lowered significantly compared to the 32.5 Ω/sq of the pure ITO. As shown, many configurations achieve even lower than 2.0 Ω/sq, which can be a desirable for large-scale superstrates.

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. An optoelectronic device comprising;
a photoabsorbing surface; and
a polymer layer comprising a first surface and a second surface, wherein the first surface defines a plurality of triangular grooves filled with a conductive material, wherein the filled triangular grooves form three-dimensional contacts that includes at least one surface such that at least a portion of radiation incident on the surface is redirected onto the photoabsorbing surface.

2. The optoelectronic device of claim 1, wherein the photoabsorbing surface comprises a material selected from the group consisting of: a III-V material, GaAs, CdTe, GICS, perovskite, and silicon.

3. The optoelectronic device of claim 1, further comprising a plurality of existing metallic contacts on the photoabsorbing surface.

4. The optoelectronic device of claim 3, further comprising solder material in contact with at least one of the existing contacts and the conductive material of at least one of the plurality of triangular grooves.

5. The optoelectronic device of claim 1, further comprising a layer of transparent conductive oxide in contact with the photoabsorbing surface and the polymer layer.

6. The optoelectronic device of claim 5, wherein the layer of transparent conductive oxide comprises a transparent conductive oxide material selected from the group consisting of: indium tin oxide and fluorine doped tin oxide.

7. The optoelectronic device of claim 5, wherein the layer of transparent conductive oxide has a thickness of less than 200 nm.

8. The optoelectronic device of claim 1, wherein the polymer layer comprises a material selected from the group consisting of: ethylene-vinyl acetate, polydimethylsiloxane, polyurethane, and polymethylmethacrylate.

9. The optoelectronic device of claim 1, wherein the conductive material comprises silver nanoparticle ink.

10. The optoelectronic device of claim 1, wherein the conductive material is a composite comprising a triangular core in contact with at least two reflective surfaces.

11. The optoelectronic device of claim 1, wherein at least one of the plurality of triangular grooves have a height-to-width aspect ratio of at least 2:1.

12. The optoelectronic device of claim 11, wherein at least one of the plurality of triangular grooves have a height of approximately 15 μm and a width of approximately 5 μm.

13. The optoelectronic device of claim 1, wherein the plurality of triangular grooves is in a grid pattern.

14. The optoelectronic device of claim 1, wherein the polymer layer has a thickness of less than 500 μm.

15. The optoelectronic device of claim 1, further comprising a sub silicon solar cell.

16. The optoelectronic device of claim 1, further comprising a lamination layer in contact with the second surface of the polymer layer.

17. A method of manufacturing a superstrate integrated with an optoelectronic device, the method comprising:
providing a layer of transparent polymer;
forming a plurality of grooves within the layer of transparent polymer;
infilling the plurality of grooves with a conductive material; and
integrating the layer of transparent polymer with an optoelectronic device.

18. The method of claim 17, wherein the plurality of grooves is infilled using an electroplating process.

19. The method of claim 17, wherein the optoelectronic device comprises a layer of transparent conductive oxide; and the layer of transparent polymer is in contact with the layer of transparent conductive oxide after integration with the optoelectronic device.

20. An optoelectronic device comprising:
a photoabsorbing surface comprising perovskite;
a layer of polydimethylsiloxane in contact with the photoabsorbing surface; and
a layer of indium tin oxide in contact with the photoabsorbing surface and the layer of polydimethylsiloxane;
wherein:
the layer of polydimethylsiloxane comprises a first surface and a second surface;
the first surface defines a plurality of triangular grooves filled with silver nanoparticle ink; and
at least one of the plurality of triangular grooves have a cross-section with a height-to-width ratio of at least 2:1.
